(19) United States
(12) Patent Application Publication
(10) Pub. No.: US 2021/0383879 A1
(43) Pub. Date: Dec. 9, 2021

(54) COUPLING CAPACITANCE REDUCTION DURING PROGRAM VERIFY FOR PERFORMANCE IMPROVEMENT

(71) Applicant: SanDisk Technologies LLC, Addison, TX (US)

(72) Inventors: Lei Lin, Fremont, CA (US); Wei Zhao, Fremont, CA (US); Henry Chin, Fremont, CA (US); Yen-Lung Li, San Jose, CA (US)

(73) Assignee: SanDisk Technologies LLC, Addison, TX (US)

(21) Appl. No.: 16/893,859

(22) Filed: Jun. 5, 2020

(51) Int. Cl. G11C 16/34; G11C 16/14; G11C 16/30; G11C 16/26; G11C 16/08

(52) U.S. Cl. CPC G11C 16/3459; G11C 16/14; G11C 16/08; G11C 16/26; G11C 16/30

(57) ABSTRACT

A memory apparatus and method of operation is provided. The apparatus includes selected memory cells coupled to a selected word line and each storing a threshold voltage representative of a selected cell data programmed in a program-verify operation. Unselected memory cells are coupled to a neighbor word line disposed adjacent the selected word line. A control circuit is coupled to the selected and unselected memory cells and configured to ramp from at least one initial voltage applied to the neighbor word line directly to a target neighbor verify voltage without exceeding or falling below the target neighbor verify voltage thereby assisting the selected word line reach at least one verify reference voltage used in verifying the threshold voltage of the selected memory cells during at least one verify stage of the program-verify operation following a program operation of the program-verify operation.

### FIELD

This application relates to non-volatile memory apparatuses and the operation of non-volatile memory apparatuses.

### BACKGROUND

This section provides background information related to the technology associated with the present disclosure and, as such, is not necessarily prior art.

Semiconductor memory apparatuses have become more popular for use in various electronic devices. For example, non-volatile semiconductor memory is used in cellular telephones, digital cameras, personal digital assistants, mobile computing devices, non-mobile computing devices and other devices.

As storage devices continue to be fabricated with increased storage density and decreased physical size, the time needed to reliably complete programming or read operations in the non-volatile memory cells of those storage devices can vary greatly. The variance in read and/or program operation time can vary on a lot-by-lot, die-by-die and/or on a smaller scale within a die due to process variations at the manufacturing stage. Separately or in addition to manufacturing variations, the read and program operation times of higher density memory devices can be affected by data pattern variations. For example, the differing combinations of high or low voltages applied to a particular block of non-volatile memory can lead to capacitive coupling between adjacent bit lines or word lines that can influence programming and read operation times. Similarly, operating temperature variations can lead to different read or program operation times between particular die, bit lines or word lines.

### SUMMARY

This section provides a general summary of the present disclosure and is not a comprehensive disclosure of its full scope or all of its features and advantages.

An object of the present disclosure is to provide a memory apparatus and a method of operating the memory apparatus that address and overcome the above-noted shortcomings.

Accordingly, it is an aspect of the present disclosure to provide an apparatus including a plurality of selected memory cells coupled to a selected word line and each storing a threshold voltage representative of a selected cell data programmed in a program-verify operation. The apparatus also includes a plurality of unselected memory cells coupled to a neighbor word line disposed adjacent the selected word line. In addition, the apparatus includes a control circuit coupled to the plurality of selected and the plurality of unselected memory cells and configured to ramp from at least one initial voltage applied to the neighbor word line directly to a target neighbor verify voltage without exceeding or falling below the target neighbor verify voltage thereby assisting the selected word line reach at least one verify reference voltage used in verifying the threshold voltage of each of the plurality of selected memory cells during at least one verify stage of the program-verify operation following a program stage of the program-verify operation.

According to another aspect of the disclosure a controller in communication with a memory apparatus including a plurality of selected memory cells coupled to a selected word line is provided. Each of plurality of selected memory cells storing a threshold voltage representative of a selected cell data programmed in a program-verify operation. The memory apparatus also includes a plurality of unselected memory cells coupled to a neighbor word line disposed adjacent the selected word line. The controller is configured to instruct the memory apparatus to ramp from at least one initial voltage applied to the neighbor word line directly to a target neighbor verify voltage without exceeding or falling below the target neighbor verify voltage thereby assisting the selected word line reach at least one verify reference voltage used in verifying the threshold voltage of each of the plurality of selected memory cells during at least one verify stage of the program-verify operation following a program stage of the program-verify operation.

According to an additional aspect of the disclosure a method of operating a memory apparatus including a plurality of selected memory cells coupled to a selected word line is also provided. Each of plurality of selected memory cells storing a threshold voltage representative of a selected cell data programmed in a program-verify operation. The memory apparatus also includes a plurality of unselected memory cells coupled to a neighbor word line disposed adjacent the selected word line. The method includes the step of ramping from at least one initial voltage applied to the neighbor word line directly to a target neighbor verify voltage without exceeding or falling below the target neighbor verify voltage during at least one verify stage of the program-verify operation following a program stage of the program-verify operation. The method also includes the step of assisting the selected word line reach at least one verify reference voltage used in verifying the threshold voltage of each of the plurality of selected memory cells.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1A is a block diagram of an exemplary non-volatile memory system according to aspects of the disclosure;

FIG. 1B is a block diagram of a storage module that includes a plurality of non-volatile memory systems according to aspects of the disclosure;

FIG. 1C is a block diagram of a hierarchical storage system according to aspects of the disclosure;

FIG. 2A is a block diagram of exemplary components of a controller of the non-volatile memory system of FIG. 1A according to aspects of the disclosure;

FIG. 2B is a block diagram of exemplary components of a non-volatile memory die of the non-volatile memory system of FIG. 1A according to aspects of the disclosure;

FIG. 3 is a circuit diagram of an example floating gate transistor according to aspects of the disclosure;

FIG. 4 is a graph of curves of drain-to-source current as a function of control gate voltage drawn through a floating gate transistor according to aspects of the disclosure;

FIG. 5A is a block diagram of a plurality of memory cells organized into blocks according to aspects of the disclosure;

FIG. 5B is a block diagram of a plurality of memory cells organized into blocks in different planes according to aspects of the disclosure;

FIG. 6 is a circuit diagram of an example two-dimensional NAND-type flash memory array according to aspects of the disclosure;

FIG. 7 is an example physical structure of a three-dimensional (3-D) NAND string according to aspects of the disclosure;

FIG. 8A is a cross-sectional view along the bit line direction (along the y-direction) of an example memory structure in which straight vertical NAND strings extend from common source connections in or near a substrate to global bit lines that extend over physical levels of memory cells according to aspects of the disclosure;

FIG. 8B is a circuit diagram of separately-selectable sets of NAND strings of FIG. 8A according to aspects of the disclosure;

FIG. 8C is a circuit diagram of a separately selectable set of NAND strings in cross section along the x-z plane according to aspects of the disclosure;

FIG. 9A is a plot of threshold voltage distribution curves for memory cells storing two bits of data according to aspects of the disclosure;

FIG. 9B is a plot of threshold voltage distribution curves for memory cells storing three bits of data according to aspects of the disclosure;

FIG. 9C is a plot of threshold voltage distribution curves for memory cells storing four bits of data according to aspects of the disclosure;

FIG. 10 is a block diagram of an example configuration of a sense block of FIG. 2B according to aspects of the disclosure;

FIG. 11A shows voltages applied to a selected word line and neighbor word line during a conventional program verify operation and a control gate reference voltage tracking mode in which a voltage of a neighbor word line tracks a control gate reference voltage applied to the selected word line over time during a program-verify operation according to aspects of the disclosure;

FIG. 11B shows a table of voltages applied to the selected word line and neighbor word line with and without the control gate reference voltage tracking mode according to aspects of the disclosure;

FIG. 12 illustrates widths of threshold voltage distributions with and without the control gate reference voltage tracking mode at a low, a regular temperature, and a high temperature for various lengths of time periods of a verify stage of the program-verify operation according to aspects of the disclosure;

FIG. 13 shows a threshold voltage distribution width for a state A, a state B, and state C for various lengths of a plurality of time periods of the verify stage of the program-verify operation according to aspects of the disclosure;

FIG. 14A shows a verify voltage waveform applied to the selected word line and neighbor word line for the state A without the control gate reference voltage tracking mode according to aspects of the disclosure;

FIG. 14B shows the verify voltage waveform applied to the selected word line ramping down to a target verify voltage according to aspects of the disclosure;

FIG. 14C shows a median tailfactor plotted versus a threshold voltage without the control gate reference voltage tracking mode according to aspects of the disclosure;

FIG. 15A shows a verify voltage waveform applied to the selected word line and neighbor word line for the state A with and without the control gate reference voltage tracking mode according to aspects of the disclosure;

FIG. 15B shows a tailfactor plotted versus a threshold voltage of the state A with and without the control gate reference voltage tracking mode at different temperatures according to aspects of the disclosure;

FIG. 16A shows a verify voltage waveform applied to the selected word line and neighbor word line for the state B and the state C with and without the control gate reference voltage tracking mode according to aspects of the disclosure;

FIG. 16B shows a tailfactor plotted versus a threshold voltage of the state B with and without the control gate reference voltage tracking mode at the high temperature according to aspects of the disclosure;

FIG. 17 shows a verify voltage waveform applied to the selected word line and neighbor word line for the state C and a state D with and without the control gate reference voltage tracking mode according to aspects of the disclosure;

FIGS. 18A and 18B show a verify voltage waveform applied to the selected word line and neighbor word line with the control gate reference voltage tracking mode and with a first modified control gate reference voltage tracking mode according to aspects of the disclosure;

FIGS. 19A and 19B show a verify voltage waveform applied to the selected word line and neighbor word line with the control gate reference voltage tracking mode and with a second modified control gate reference voltage tracking mode according to aspects of the disclosure;

FIG. 20 shows a table with an exemplary implementation of the first and second modified control gate reference voltage tracking modes according to aspects of the disclosure;

FIG. 21 illustrates steps of a method of operating the non-volatile memory system according to aspects of the disclosure;

FIG. 22 shows threshold voltage distribution width plotted versus a program time for the non-volatile memory system with the first and second modified control gate reference voltage tracking modes compared to the control gate reference voltage tracking mode and without the control gate reference voltage tracking mode according to aspects of the disclosure;

FIG. 23 shows a threshold voltage distribution width for the state B, the state C, and the state D for various lengths of a time period after the plurality of time periods of the verify stage of the program-verify operation according to aspects of the disclosure;

FIG. 24 shows a threshold voltage distribution width versus a default read pass voltage for each of the state A, the state B, the state C, and the state D according to aspects of the disclosure;

FIG. 25 shows a threshold voltage distribution width for different lengths of the plurality of time periods at the regular temperature according to aspects of the disclosure;

FIG. 26 shows a threshold voltage distribution width for different lengths of the plurality of time periods at the high temperature according to aspects of the disclosure;

FIGS. 27 and 28 show a threshold voltage distribution width for different lengths of the plurality of time periods at the regular and high temperatures for the state B according to aspects of the disclosure; and

FIGS. 29 and 30 show a threshold voltage Vth distribution width for different lengths of the plurality of time periods at the regular and high temperatures for the state C according to aspects of the disclosure.

### DETAILED DESCRIPTION

In the following description, details are set forth to provide an understanding of the present disclosure. In some instances, certain circuits, structures and techniques have not been described or shown in detail in order not to obscure the disclosure.

In general, the present disclosure relates to non-volatile memory apparatuses of the type well-suited for use in many applications. The non-volatile memory apparatus and associated methods of forming of this disclosure will be described in conjunction with one or more example embodiments. However, the specific example embodiments disclosed are merely provided to describe the inventive concepts, features, advantages and objectives with sufficient clarity to permit those skilled in this art to understand and practice the disclosure. Specifically, the example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

In some memory devices or apparatuses, memory cells are joined to one another such as in NAND strings in a block or sub-block. Each NAND string comprises a number of memory cells connected in series between one or more drain-side SG transistors (SGD transistors), on a drain-side of the NAND string which is connected to a bit line, and one or more source-side SG transistors (SGS transistors), on a source-side of the NAND string which is connected to a source line. Further, the memory cells can be arranged with a common control gate line (e.g., word line) which acts a control gate. A set of word lines extends from the source side of a block to the drain side of a block. Memory cells can be connected in other types of strings and in other ways as well.

In a 3D memory structure, the memory cells may be arranged in vertical strings in a stack, where the stack comprises alternating conductive and dielectric layers. The conductive layers act as word lines which are connected to the memory cells. The memory cells can include data memory cells, which are eligible to store user data, and dummy or non-data memory cells which are ineligible to store user data.

During a program operation, the memory cells are programmed according to a word line programming order. For example, the programming may start at the word line at the source side of the block and proceed to the word line at the drain side of the block. In one approach, each word line is completely programmed before programming a next word line. For example, a first word line, WL0, is programmed using one or more programming pulses until the programming is completed. Next, a second word line, WL1, is programmed using one or more programming pulses until the programming is completed, and so forth. A programming pulse may include a set of increasing program voltages which are applied to the word line in respective program loops or program-verify iterations. Verify operations or stages may be performed after each program voltage to determine whether the memory cells have completed programming. When programming is completed for a memory cell, it can be locked out from further programming while programming continues for other memory cells in subsequent program loops.

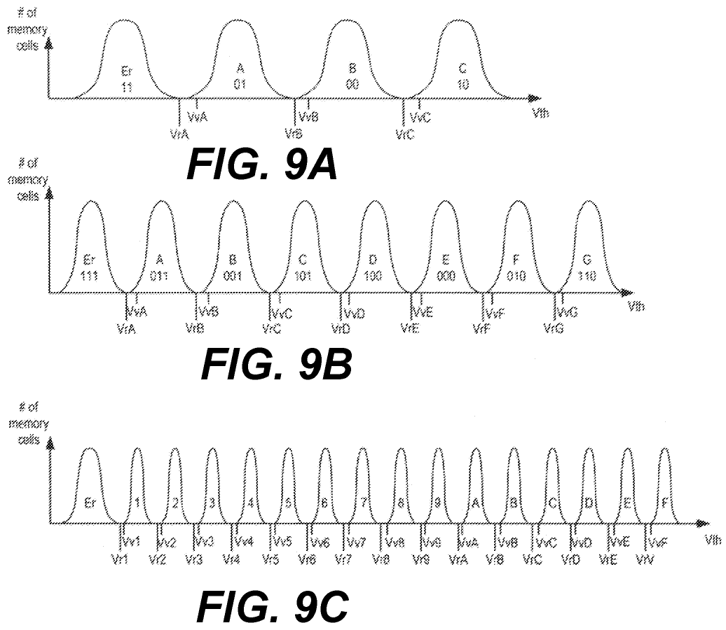

Each memory cell may be associated with a data state according to write data in a program command. Based on its data state, a memory cell will either remain in the erased state or be programmed to a programmed data state. For example, in a one bit per cell memory device, there are two data states including the erased state and the programmed state. In a two-bit per cell memory device, there are four data states including the erased state and three higher data states referred to as the A, B and C data states (see FIG. 9A). In a three-bit per cell memory device, there are eight data states including the erased state and seven higher data states referred to as the A, B, C, D, E, F and G data states (see FIG. 9B). In a four-bit per cell memory device, there are sixteen data states including the erased state and fifteen higher data states (see FIG. 9C).

After the memory cells are programmed, the data can be read back in a read operation. A read operation can involve applying a series of read voltages to a word line while sensing circuitry determines whether cells connected to the word line are in a conductive or non-conductive state. If a cell is in a non-conductive state, the threshold voltage Vt or Vth of the memory cell exceeds the read voltage. The read voltages are set at levels which are expected to be between the threshold voltage levels of adjacent data states.

It is desirable to increase programming speed of a memory apparatus. One way to improve programming performance or speed is to reduce verify time during or after programming. However, such reductions in verify time can sometimes lead to degradation in Vt margins (i.e., spacing between Vt distributions of data states).

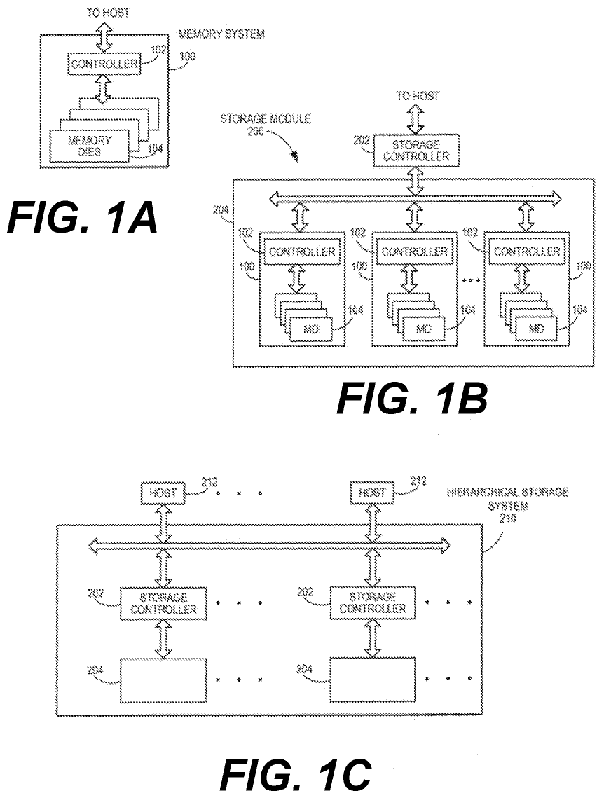

FIG. 1A is a block diagram illustrating a memory system 100. The memory system 100 may include a controller 102 and memory that may be made up of one or more memory dies 104. As used herein, the term die refers to the set of memory cells, and associated circuitry for managing the physical operation of those memory cells, that are formed on a single semiconductor substrate. The controller 102 may interface with a host system and transmit command sequences for read, program, and erase operations to the non-memory die(s) 104.

The controller 102 (which may be a flash memory controller) can take the form of processing circuitry, a microprocessor or processor, and a computer-readable medium that stores computer-readable program code (e.g., software or firmware) executable by the (micro)processor, logic gates, switches, an application specific integrated circuit (ASIC), a programmable logic controller, and an embedded microcontroller, for example. The controller 102 can be configured with hardware and/or firmware to perform the various functions described below and shown in the flow diagrams. Also, some of the components shown as being internal to the controller can also be stored external to the controller, and other components can be used. Additionally, the phrase “operatively in communication with” could mean directly in communication with or indirectly (wired or wireless) in communication with through one or more components, which may or may not be shown or described herein.

As used herein, the controller 102 is a device that manages data stored in the memory die(s) and communicates with a host, such as a computer or electronic device. The controller 102 can have various functionality in addition to the specific functionality described herein. For example, the controller 102 can format the memory dies 104 to ensure that they are operating properly, map out bad flash memory cells, and allocate spare cells to be substituted for future failed cells. Some part of the spare cells can be used to hold firmware to operate the controller 102 and implement other features. In operation, when a host needs to read data from or write data to the memory die(s) 104, the host will communicate with the controller 102. If the host provides a logical address to which data is to be read/written, the controller 102 can convert the logical address received from the host to a physical address in the memory die(s) 104. (Alternatively, the host can provide the physical address). The controller 102 can also perform various memory management functions, such as, but not limited to, wear leveling (distributing writes to avoid wearing out specific blocks of memory that would otherwise be repeatedly written to) and garbage collection (after a block is full, moving only the valid pages of data to a new block, so the full block can be erased and reused).

The interface between the controller 102 and the non-volatile memory die(s) 104 may be any suitable interface, such as flash interface, including those configured for Toggle Mode 200, 400, 800, 1000 or higher. For some example embodiments, the memory system 100 may be a card based system, such as a secure digital (SD) or a micro secure digital (micro-SD) card. In alternate example embodiments, the memory system 100 may be part of an embedded memory system.

In the example illustrated in FIG. 1A, the memory system 100 is shown as including a single channel between the controller 102 and the non-volatile memory die(s) 104. However, the subject matter described herein is not limited to memory systems having a single memory channel. For example, in some memory systems, such as those embodying NAND architectures, 2, 4, 8 or more channels may exist between the controller 102 and the memory die(s) 104, depending on controller capabilities. In any of the embodiments described herein, more than a single channel may exist between the controller and the memory die(s)s 104, even if a single channel is shown in the drawings.

FIG. 1B illustrates a storage module 200 that includes plural non-volatile memory systems 100. As such, the storage module 200 may include a storage controller 202 that interfaces with a host and with a storage system 204, which includes a plurality of non-volatile memory systems 100. The interface between the storage controller 202 and non-volatile memory systems 100 may be a bus interface, such as a serial advanced technology attachment (SATA), a peripheral component interface express (PCIe) interface, an embedded MultiMediaCard (eMMC) interface, a SD interface, or a Universal Serial Bus (USB) interface, as examples. The storage module 200, in one embodiment, may be a solid state drive (SSD), such as found in portable computing devices, such as laptop computers and tablet computers, and mobile phones.

FIG. 1C is a block diagram illustrating a hierarchical storage system 210. The hierarchical storage system 210 may include a plurality of storage controllers 202, each of which control a respective storage system 204. Host systems 212 may access memories within the hierarchical storage system 210 via a bus interface. Example bus interfaces may include a non-volatile memory express (NVMe), a fiber channel over Ethernet (FCoE) interface, an SD interface, a USB interface, a SATA interface, a PCIe interface, or an eMMC interface as examples. In one embodiment, the storage system 210 illustrated in FIG. 1C may be a rack mountable mass storage system that is accessible by multiple host computers, such as would be found in a data center or other location where mass storage is needed.

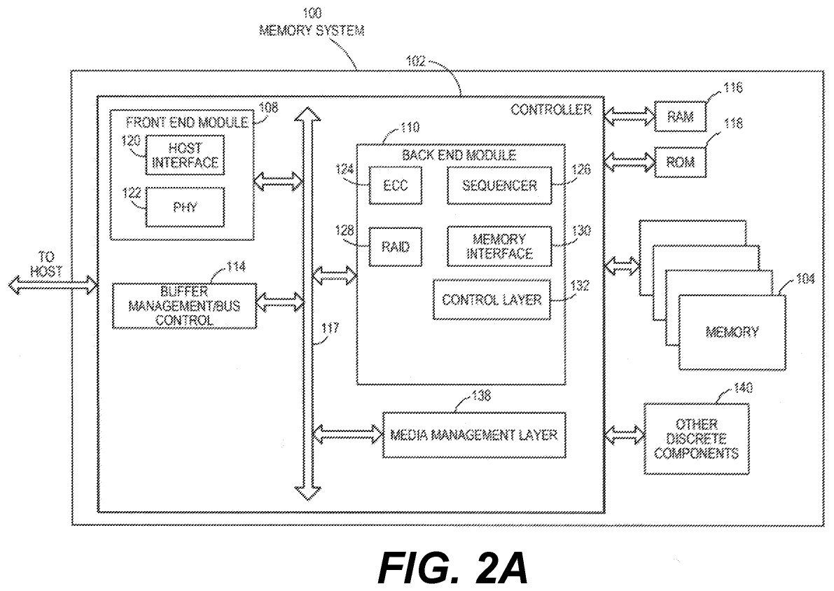

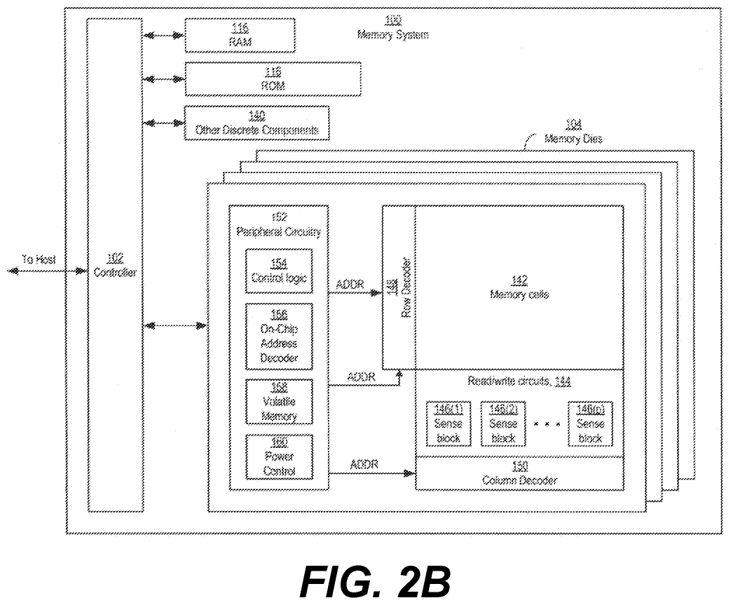

FIG. 2A is a block diagram illustrating exemplary components of the controller 102 in more detail. The controller 102 may include a front end module 108 that interfaces with a host, a back end module 110 that interfaces with the non-volatile memory die(s) 104, and various other modules that perform various functions of the non-volatile memory system 100. In general, a module may be hardware or a combination of hardware and software. For example, each module may include an application specific integrated circuit (ASIC), a field programmable gate array (FPGA), a circuit, a digital logic circuit, an analog circuit, a combination of discrete circuits, gates, or any other type of hardware or combination thereof. In addition or alternatively, each module may include memory hardware that comprises instructions executable with a processor or processor circuitry to implement one or more of the features of the module. When any one of the modules includes the portion of the memory that comprises instructions executable with the processor, the module may or may not include the processor. In some examples, each module may just be the portion of the memory that comprises instructions executable with the processor to implement the features of the corresponding module without the module including any other hardware. Because each module includes at least some hardware even when the included hardware comprises software, each module may be interchangeably referred to as a hardware module.

The controller 102 may include a buffer manager/bus controller module 114 that manages buffers in random access memory (RAM) 116 and controls the internal bus arbitration for communication on an internal communications bus 117 of the controller 102. A read only memory (ROM) 118 may store and/or access system boot code. Although illustrated in FIG. 2A as located separately from the controller 102, in other embodiments one or both of the RAM 116 and the ROM 118 may be located within the controller 102. In yet other embodiments, portions of RAM 116 and ROM 118 may be located both within the controller 102 and outside the controller 102. Further, in some implementations, the controller 102, the RAM 116, and the ROM 118 may be located on separate semiconductor dies.

Additionally, the front end module 108 may include a host interface 120 and a physical layer interface (PHY) 122 that provide the electrical interface with the host or next level storage controller. The choice of the type of the host interface 120 can depend on the type of memory being used. Example types of the host interface 120 may include, but are not limited to, SATA, SATA Express, SAS, Fibre Channel, USB, PCIe, and NVMe. The host interface 120 may typically facilitate transfer for data, control signals, and timing signals.

The back end module 110 may include an error correction code (ECC) engine or module 124 that encodes the data bytes received from the host, and decodes and error corrects the data bytes read from the non-volatile memory die(s) 104. The back end module 110 may also include a command sequencer 126 that generates command sequences, such as program, read, and erase command sequences, to be transmitted to the non-volatile memory die(s) 104. Additionally, the back end module 110 may include a RAID (Redundant Array of Independent Drives) module 128 that manages generation of RAID parity and recovery of failed data. The RAID parity may be used as an additional level of integrity protection for the data being written into the non-volatile memory system 100. In some cases, the RAID module 128 may be a part of the ECC engine 124. A memory interface 130 provides the command sequences to the non-volatile memory die(s) 104 and receives status information from the non-volatile memory die(s) 104. Along with the command sequences and status information, data to be programmed into and read from the non-volatile memory die(s) 104 may be communicated through the memory interface 130. In one embodiment, the memory interface 130 may be a double data rate (DDR) interface and/or a Toggle Mode 200, 400, 800, or higher interface. A control layer 132 may control the overall operation of back end module 110.

Additional modules of the non-volatile memory system 100 illustrated in FIG. 2A may include a media management layer 138, which performs wear leveling of memory cells of the non-volatile memory die 104, address management, and facilitates folding operations as described in further detail below. The non-volatile memory system 100 may also include other discrete components 140, such as external electrical interfaces, external RAM, resistors, capacitors, or other components that may interface with controller 102. In alternative embodiments, one or more of the RAID module 128, media management layer 138 and buffer management/bus controller 114 are optional components that may not be necessary in the controller 102.

FIG. 2B is a block diagram illustrating exemplary components of a memory die 104 in more detail. The memory die 104 may include a memory cell structure 142 that includes a plurality of memory cells or memory elements. Any suitable type of memory can be used for the memory cells 142. As examples, the memory can be dynamic random access memory (“DRAM”) or static random access memory (“SRAM”), non-volatile memory, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory may have different configurations. For example, flash memory devices may be configured in a NAND or a NOR configuration.

The memory can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are exemplary, and memory elements may be otherwise configured.

The semiconductor memory elements located within and/or over a substrate may be arranged in two or three dimensions, such as a two dimensional memory structure or a three dimensional memory structure.

In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate).

As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in the y direction) with each column having multiple memory elements in each column. The columns may be arranged in a two dimensional configuration, e.g., in an x-z plane, resulting in a three dimensional arrangement of memory elements with elements on multiple vertically stacked memory planes. Other configurations of memory elements in three dimensions can also constitute a three dimensional memory array.

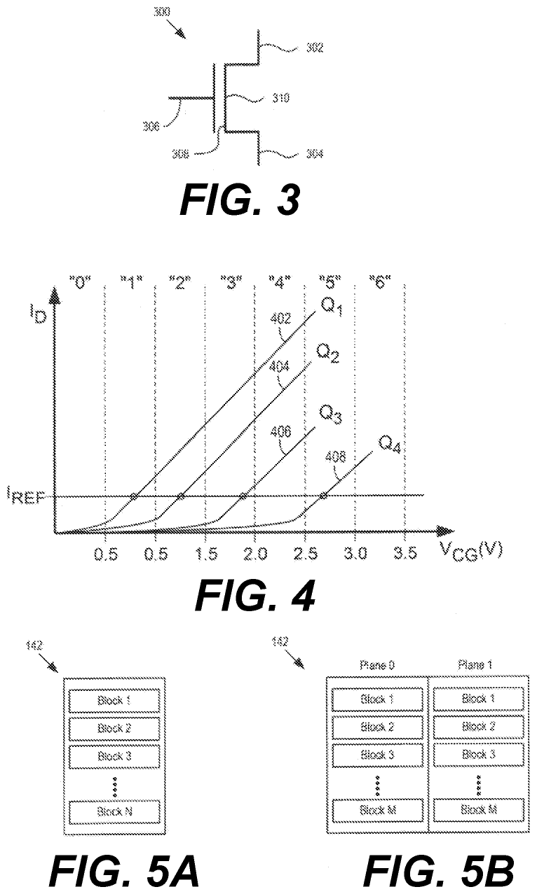

For some memory configurations, such as flash memory, a memory cell of the plurality of memory cells 142 may be a floating gate transistor (FGT). FIG. 3 shows a circuit schematic diagram of an example FGT 300. The FGT 300 may include a source 302, a drain 304, a control gate 306, a floating gate 308, and a substrate 310. The floating gate 308 may be surrounded by an insulator or insulating material that helps retain charge in the floating gate 308. The presence or absence of charges inside the floating gate 308 may cause a shift in a threshold voltage of the FGT, which is used to distinguish logic levels. For each given charge stored in the floating gate 308, a corresponding drain-to-source conduction current ID with respect to a fixed control gate Voltage VCG applied to the control gate 306 occurs. Additionally, the FGT 300 may have associated range charges that can be programmable onto its floating gate 308 that define a corresponding threshold voltage window or a corresponding conduction current window. In this way, the FGT's threshold voltage may be indicative of the data stored in the memory cell.

FIG. 4 is graph showing four curves 402, 404, 406, 408 of drain-to-source current ID drawn through the FGT 300 as a function of a control gate voltage VCG applied to the control gate 306. Each curve 402-408 corresponds to a respective one of four different charges or charge levels Q1, Q2, Q3, Q4 that the floating gate 308 can selectively store at any given time. Otherwise stated, the four curves 402-408 represent four possible charge levels that can be programmed on the floating gate 308 of the FGT 300, respectively corresponding to four possible memory or data states. In the example graph in FIG. 4, the threshold voltage window of a population of FGTs range from 0.5 volts (V) to 3.5 V. Seven possible memory or data states “0”, “1”, “2”, “3”, “4”, “5”, and “6” are defined or extend across the threshold voltage window or common range of threshold voltages Vth, and respectively represent one erased states and six programmed states. The different states can be demarcated by partitioning the threshold voltage window into six regions of 0.5 V intervals. The FGT 300 may be in one of the memory states according to the charge stored in its floating gate 308 and where its drain-to-source current ID intersects a reference current IREF. For example, a FGT programmed to store charge Q1 in memory state “1” since its curve 402 intersects the reference current IREF in a region of the threshold voltage region demarcated by the control gate voltage VCG in a range from 0.5 V to 1.0 V. The more memory states the FGT 300 is programmed to store, the more finely divided are the regions defining the threshold voltage window. In some examples configurations, the threshold voltage window may extend from −1.5 V to 5 V, providing a maximum width of 6.5 V. If the FGT 300 can be programmed into any one of sixteen possible memory states, each memory state may occupy a respective region spanning 200 millivolts (mV) to 300 mV. The higher the resolution of the threshold voltage window (i.e., more memory states into which the FGT 300 can be programmed), the higher the precision that is needed in programming and reading operations to successfully read and write data. Further description of memory states and threshold voltages is provided in further detail below with respect to programming, program-verify, and read operations.

Referring to FIG. 5A, the memory cells 142 may be organized into an N-number of blocks, extending from a first block Block 1 to an Nth block Block N. Referring to FIG. 5B, for some example configurations, the N-number of blocks are organized into a plurality of planes. FIG. 5B shows an example configuration where the blocks are organized into two planes, including a first plane Plane 0 and a second plane Plane 1. Each plane is shown as included an M-number of blocks, extending from a first block Block 1 to an Mth block Block M. Data stored in different planes may be sensed simultaneously or independently.

For configurations where the memory cells are organized into a two-dimensional array, the memory cells may be configured in a matrix-like structure of rows and columns in each of the blocks. At the intersection of a row and a column is a memory cell. A column of memory cells is a referred to as a string, and memory cells in a string are electrically connected in series. A row of memory cells is referred to as a page. Where the memory cells are FGTs, control gates of FGTs in a page or row may be electrically connected together.

Additionally, each of the blocks includes word lines and bit lines connected to the memory cells. Each page of memory cells is coupled to a word line. Where the memory cells are FGTs, each word line may be coupled to the control gates of the FGTs in a page. In addition, each string of memory cells is coupled to a bit line. Further, a single string may span across multiple word lines, and the number of memory cells in a string may be equal to the number of pages in a block.

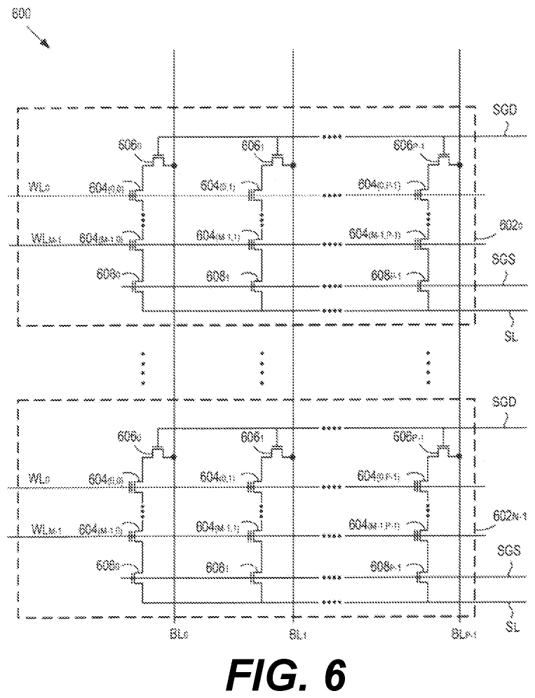

FIG. 6 is a circuit schematic diagram of at least a portion of an exemplary two-dimensional NAND-type flash memory array 600, which may be representative of at least a portion of the plurality of memory cells 142 (FIG. 2B). For example, the memory array 600 may be representative of a single plane of blocks on a memory die 104. The memory array 600 may include an N-number of blocks 602 o to 602N-1. Each block 602 includes a P-number of strings of FGTs 604, with each string coupled to respective one of a P-number of bit lines BL0 to BLP−1. Additionally, each block 602 includes an M-number of pages of FGTs 604, with each page coupled to a respective one of an M-number of word lines WL0 to WLM−1. Each ith, jth FGT(i,j) of a given block 602 is connected to an ith word line WLi and to a jth bit line BLj of the given block. As shown in FIG. 6, bit lines BL0 to BLP−1 are shared among the blocks 602 0 to 602 N−1 may be which are shared among the blocks, such as blocks within the same plane.

Within each block 602, each string is connected at one end to an associated drain select gate transistor 606, and each string is coupled to its associated bit line BL via the associated drain select gate transistor 606. Switching of the drain select gate transistors 606 0 to 606 P−1 may be controlled using a drain select gate bias line SGD that supplies a drain select gate bias voltage VSGD to turn on and off the drain select transistors 606 0 to 606 P−1. In addition, within each block 602, each string is connected at its other end to an associated source select gate transistor 608, and each string is coupled to a common source line SL via the associated source select gate transistor 608. Switching of the source select gate transistors 608 0 to 608 P−1 may be controlled using a source select gate bias line SGS that supplies a source select gate bias voltage VSGS to turn on and off the source select transistors 608 0 to 608 P−1. Also, although not shown, in some cases, dummy word lines, which contain no user data, can also be used in the memory array 600 adjacent to the source select gate transistors 608 0 to 608 P−1. The dummy word lines may be used to shield edge word lines and FGTs from certain edge effects.

An alternative arrangement to a conventional two-dimensional (2-D) NAND array is a three-dimensional (3-D) array. In contrast to 2-D NAND arrays, which are formed along a planar surface of a semiconductor wafer, 3-D arrays extend up from the wafer surface and generally include stacks, or columns, of memory cells extending upwards. Various 3-D arrangements are possible. In one arrangement a NAND string is formed vertically with one end (e.g. source) at the wafer surface and the other end (e.g. drain) on top. In another arrangement a NAND string is formed in a U-shape so that both ends of the NAND string are accessible on top, thus facilitating connections between such strings.

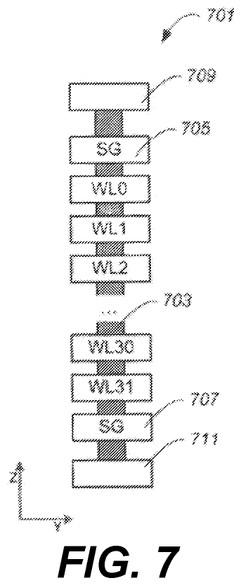

FIG. 7 shows a first example of a NAND string 701 that extends in a vertical direction, i.e. extending in the z-direction, perpendicular to the x-y plane of the substrate. Memory cells are formed where a vertical bit line (local bit line) 703 passes through a word line (e.g. WL0, WL1, etc.). A charge trapping layer between the local bit line and the word line stores charge, which affects the threshold voltage of the transistor formed by the word line (gate) coupled to the vertical bit line (channel) that it encircles. Such memory cells may be formed by forming stacks of word lines and then etching memory holes where memory cells are to be formed. Memory holes are then lined with a charge trapping layer and filled with a suitable local bit line/channel material (with suitable dielectric layers for isolation).

As with two-dimensional (planar) NAND strings, select gates 705, 707, are located at either end of the string to allow the NAND string to be selectively connected to, or isolated from, external elements 709, 711. Such external elements are generally conductive lines such as common source lines or bit lines that serve large numbers of NAND strings. Vertical NAND strings may be operated in a similar manner to planar NAND strings and both Single Level Cell (SLC) and Multi Level Cell (MLC) operation is possible. While FIG. 7 shows an example of a NAND string that has 32 cells (0-31) connected in series, the number of cells in a NAND string may be any suitable number. Not all cells are shown for clarity. It will be understood that additional cells are formed where word lines 3-29 (not shown) intersect the local vertical bit line.

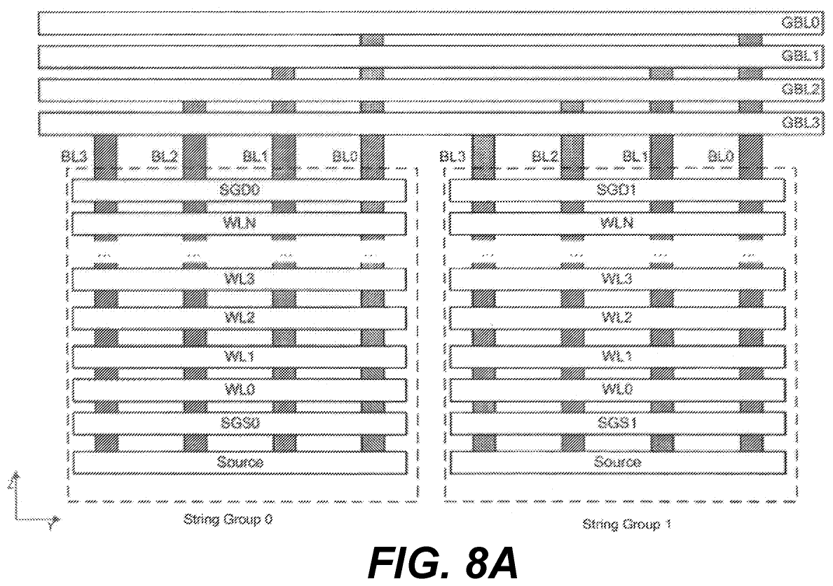

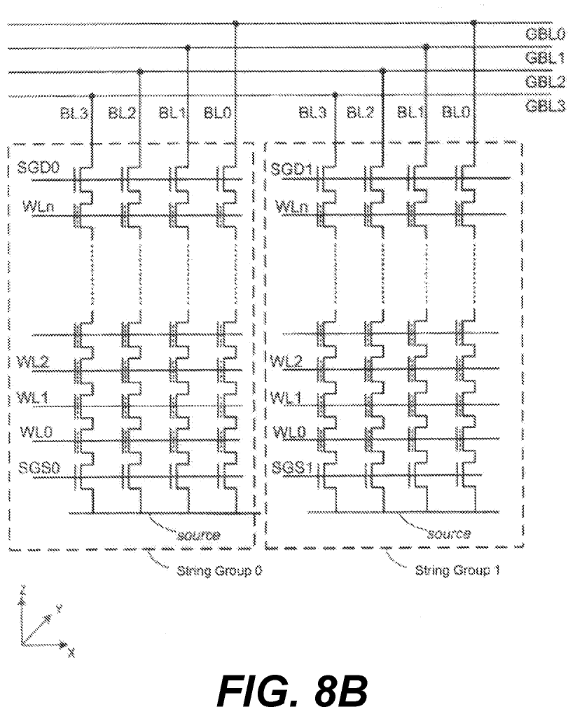

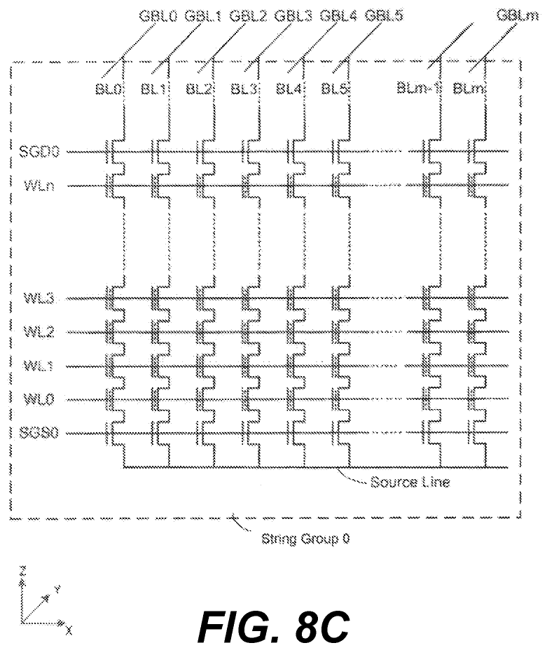

FIG. 8A shows a memory structure, in cross section along the bit line direction (along y-direction) in which straight vertical NAND strings extend from common source connections in or near a substrate to global bit lines (GBL0-GBL3) that extend over the physical levels of memory cells. Word lines in a given physical level in a block are formed from a sheet of conductive material. Memory hole structures extend down through these sheets of conductive material to form memory cells that are connected in series vertically (along the z-direction) by vertical bit lines (BL0-BL3) to form vertical NAND strings. Within a given block there are multiple NAND strings connected to a given global bit line (e.g. GBL0 connects with multiple BL0 s). NAND strings are grouped into sets of strings that share common select lines. Thus, for example, NAND strings that are selected by source select line SGS0 and drain select line SGD0 may be considered as a set of NAND strings and may be designated as String 0, while NAND strings that are selected by source select line SGS1 and drain select line SGD1 may be considered as another set of NAND strings and may be designated as String 1 as shown. A block may consist of any suitable number of such separately-selectable sets of strings. It will be understood that FIG. 8A shows only portions of GBL0-GBL3, and that these bit lines extend further in the y-direction and may connect with additional NAND strings in the block and in other blocks. Furthermore, additional bit lines extend parallel to GBL0-GBL3 (e.g. at different locations along x-axis, in front of, or behind the location of the cross-section of FIG. 8A).

FIG. 8B illustrates separately-selectable sets of NAND strings of FIG. 8A schematically. It can be seen that each of the global bit lines (GBL0-GBL3) is connected to multiple separately selectable sets of NAND strings (e.g. GBL0 connects to vertical bit line BL0 of String 0 and also connects to vertical bit line BL0 of String 1) in the portion of the block shown. In some cases, word lines of all strings of a block are electrically connected, e.g. WL0 in string 0 may be connected to WL0 of String 1, String 2, etc. Such word lines may be formed as a continuous sheet of conductive material that extends through all sets of strings of the block. Source lines may also be common for all strings of a block. For example, a portion of a substrate may be doped to form a continuous conductor underlying a block. Source and drain select lines are not shared by different sets of strings so that, for example, SGD0 and SGS0 can be biased to select String 0 without similarly biasing SGD1 and SGS1. Thus, String 0 may be individually selected (connected to global bit lines and a common source) while String 1 (and other sets of strings) remain isolated from global bit lines and the common source. Accessing memory cells in a block during programming and reading operations generally includes applying select voltages to a pair of select lines (e.g. SGS0 and SGD0) while supplying unselect voltages to all other select lines of the block (e.g. SGS1 and SGD1). Then, appropriate voltages are applied to word lines of the block so that a particular word line in the selected set of strings may be accessed (e.g. a read voltage is applied to the particular word line, while read-pass voltages are applied to other word lines). Erasing operations may be applied on an entire block (all sets of strings in a block) rather than on a particular set of strings in a block.

FIG. 8C shows a separately selectable set of NAND strings, String 0, of FIGS. 8A-B in cross section along the X-Z plane. It can be seen that each global bit line (GBL0-GBLm) is connected to one vertical NAND string (vertical bit line BL0-BLm) in String 0. String 0 may be selected by applying appropriate voltages to select lines SGD0 and SGS0. Other sets of strings are similarly connected to global bit lines (GBL0-GBLm) at different locations along the Y direction and with different select lines that may receive unselect voltages when String 0 is selected.

Referring back to FIG. 2B, the memory die 104 may further include read/write circuits 144 that includes a plurality or p-number of sense blocks (also referred to as sense modules or sense circuits) 146. As described in further detail below, the sense blocks 146 are configured to participate in reading or programming a page of memory cells in parallel.

The memory die 104 may also include a row address decoder 148 and a column address decoder 150. The row address decoder 148 may decode a row address and select a particular word line in the memory array 142 when reading or writing data to/from the memory cells 142. The column address decoder 150 may decode a column address to select a particular group of bit lines in the memory array 142 to read/write circuits 144.

In addition, the non-volatile memory die 104 may include peripheral circuitry 152. The peripheral circuitry 152 may include control logic circuitry 154, which may be implemented as a state machine, that provides on-chip control of memory operations as well as status information to the controller 102. The peripheral circuitry 152 may also include an on-chip address decoder 156 that provides an address interface between addressing used by the controller 102 and/or a host and the hardware addressing used by the row and column decoders 148, 150. In addition, the peripheral circuitry 152 may also include volatile memory 158. An example configuration of the volatile memory 158 may include latches, although other configurations are possible.

In addition, the peripheral circuitry 152 may include power control circuitry 160 that is configured to generate and supply voltages to the memory array 142, including voltages (including program voltage pulses) to the word lines, erase voltages (including erase voltage pulses), the source select gate bias voltage VSSG to the source select gate bias line SSG, the drain select gate bias voltage VDSG to the drain select gate bias line DSG, a cell source voltage Vcelsrc on the source lines SL, as well as other voltages that may be supplied to the memory array 142, the read/write circuits 144, including the sense blocks 146, and/or other circuit components on the memory die 104. The various voltages that are supplied by the power control circuitry 160 are described in further detail below. The power control circuitry 160 may include any of various circuit topologies or configurations to supply the voltages at appropriate levels to perform the read, write, and erase operations, such as driver circuits, charge pumps, reference voltage generators, and pulse generation circuits, or a combination thereof. Other types of circuits to generate the voltages may be possible. In addition, the power control circuitry 160 may communicate with and/or be controlled by the control logic circuitry 154, the read/write circuits 144, and/or the sense blocks 146 in order to supply the voltages at appropriate levels and appropriate times to carry out the memory operations.

In order to program a target memory cell, and in particular a FGT, the power control circuitry 160 applies a program voltage to the control gate of the memory cell, and the bit line that is connected to the target memory cell is grounded, which in turn causes electrons from the channel to be injected into the floating gate. During a program operation, the bit line that is connected to the target memory cell is referred to as a selected bit line. Conversely, a bit line that is not connected to a target memory cell during a program operation is referred to as an unselected bit line. In this context, a state of the bit line may refer to whether the bit line is selected or unselected. Otherwise stated, a bit line can be in one of two states, selected or unselected. When electrons accumulate in the floating gate, the floating gate becomes negatively charged and the threshold voltage Vth of the memory cell is raised. The power control circuitry 160 applies the program voltage VPGM on the word line that is connected to the target memory cell in order for the control gate of the target memory cell to receive the program voltage VPGM and for the memory cell to be programmed. As previously described, in a block, one memory cell in each of the NAND strings share the same word line. During a program operation, the word line that is connected to a target memory cell is referred to as a selected word line. Conversely, a word line that is not connected to a target memory cell during a program operation is referred to as an unselected word line.

FIGS. 9A-9C are plots of threshold voltage distribution curves for different numbers of bits being stored the memory cells over a common range of threshold voltages Vth. The threshold voltage distributions or curves are plotted for threshold voltage Vth as a function of the number of memory cells. FIG. 9A show threshold voltage distributions or curves for memory cells programmed to store two bits of data, FIG. 9B show threshold voltage Vth distributions or curves for memory cells programmed to store three bits of data, and FIG. 9C show voltage distributions or curves for memory cells programmed to store four bits of data. Similar threshold voltage Vth distributions or curves may be generated for memory cells programmed to store numbers of bits other than two, three, and four.

At a given point in time, each memory cell may be a particular one of a plurality of memory states (otherwise referred to as a data state). The memory states may include an erased stated and a plurality of programmed or data states. Accordingly, at a given point in time, each memory cell may be in the erased state or one of the plurality of programmed states. The number of programmed states corresponds to the number of bits the memory cells are programmed to store. With reference to FIG. 9A, for a memory cell programmed to store two bits, the memory cell may be in an erased state Er or one of three programmed states A, B, C. With reference to FIG. 9B, for a memory cell programmed to store three bits, the memory cell may be in an erased state Er or one of seven programmed states A, B, C, D, E, F, G. With reference to FIG. 9C, for a memory cell programmed to store four bits, the memory cell may be in an erased state Er or one of fifteen programmed states 1, 2, 3, 4, 5, 6, 7, 8, 9, A, B, C, D, E, F. As shown in FIGS. 9A-9C, each voltage distribution curve is associated with the erased state or one of the programmed states.

Additionally, each threshold voltage distribution curve defines and/or is associated with a distinct threshold voltage range that, in turn, defines, is assigned, or is associated with a distinct one of a plurality of predetermined n-bit binary values. As such, determining what threshold voltage Vth a memory cell has allows the data (i.e., the logic values of the bits) that the memory cell is storing to be determined. The specific relationship between the data programmed into the memory cells and the threshold voltage levels of the memory cell depends on the data encoding scheme used for programming the memory cells. In one example, as shown in FIGS. 9A and 9B, a Gray code scheme is used to assign data values to the threshold voltage distribution curves. Under this scheme, for memory cells programmed with two bits of data, the data value “11” is assigned to the range of threshold voltages associated with the erased state Er, the data value “01” is assigned to the range of threshold voltages associated with programmed state A, the data value “00” is assigned to the range of threshold voltages associated with programmed state B, and the data value “10” is assigned to the range of threshold voltages associated with the programmed state C. Similar relationships between data values and memory states can be made for memory cells programmed to store three bits, four bits, or other bits of data.

Prior to performance of a program operation that programs a plurality or group of target memory cells, all of the memory cells of the group subjected to and/or selected to be programmed in the program operation may be in the erased state. During the program operation, the power control circuitry 160 may apply the program voltage to a selected word line and in turn the control gates of the target memory cells as a series of program voltage pulses. The target memory cells being programmed concurrently are connected to the same, selected word line. In many program operations, the power control circuitry 160 increases the magnitude of the program pulses with each successive pulse by a predetermined step size. Also, as described in further detail below, the power control circuitry 160 may apply one or more verify pulses to the control gate of the target memory cell in between program pulses as part of a program loop or a program-verify operation. Additionally, during a program operation, the power control circuitry 160 may apply one or more boosting voltages to the unselected word lines.

The target memory cells connected to the selected word line will concurrently have their threshold voltage change, unless they have been locked out from programming. When the program operation is complete for one of the target memory cells, the target memory cell is locked out from further programming while the program operation continues for the other target memory cells in subsequent program loops. As described in greater detail below, the locking out of a target memory cell that has reached its desired memory state may be accomplished in different ways. For example, a bit line may be locked out via the control logic circuitry by applying an inhibit voltage to the bit line on which the target cell resides to prevent a current flow through the target cell that would disturb the current memory state when a next programming pulse on the word line for the target memory cell is received. Also, for some example program operations, the control logic circuitry 154 may maintain a counter that counts the program pulses.

During a program operation to program a group of target memory cells, each target memory cell is assigned to one of the plurality of memory states according to write data that is to be programmed into the target memory cells during the program operation. Based on its assigned memory state, a given target memory cell will either remain the erased state or be programmed to a programmed state different from the erased state. When the control logic 154 receives a program command from the controller 102, or otherwise determines to perform a program operation, the write data is stored in latches included in the read/write circuitry 144. During the program operation, the read/write circuitry 144 can read the write data to determine the respective memory state to which each of the target memory cells is to be programmed.

As described in further detail below, and as illustrated in FIGS. 9A-9C, each programmed state is associated with a respective verify voltage level Vv. A given target memory cell is programmed in its assigned memory state when its threshold voltage Vth is above the verify voltage Vv associated with the memory state assigned to that target memory cell. As long as the threshold voltage Vth of the given target memory cell is below the associated verify voltage Vv, the control gate of the target memory cell may be subject to a program pulse to increase the target memory cell's threshold voltage Vth to within the threshold voltage range associated with the memory state assigned to the given target memory cell. Alternatively, when the threshold voltage Vth of the given target memory cell increases to above the associated verify voltage level Vv, then programming may be complete for the given target memory cell. As described in further detail below, a sense block 146 may participate in a program-verify operation that determines whether programming for a given memory cell is complete.

In general, in a program operation, the power control circuitry 160 will apply multiple or several program pulses to the selected word line in order to program all of the target memory cells into their assigned memory or data states. The application of the multiple program pulses applied to the selected memory cell during a program operation is divided into multiple program stages. During each program stage, the power control circuitry 160 applies at least one of the program pulse of the plurality of pulses on the selected word line in order to increase the threshold voltages Vth of those target memory cells that are selected or not locked out at that point in time of the program operation.

As previously mentioned, target memory cells subject to a program operation may also be subject to a verify operation that determines when programming is complete for each of the target memory cells. The verify operation is divided into a plurality of verify stages. A verify stage is a sub-operation of a program operation (also known as a program-verify operation) during which circuitry performs a sense operation on a subset of memory cells assigned to the same memory state to determine which of the memory cells of the subset are sufficiently programed into the assigned memory state. Each verify stage is associated with one of a plurality of different memory states into which different target memory cells are to be programmed in a program operation. Each verify stage is performed to verify whether those target memory cells assigned to be programmed in the associated memory state are programmed in the associated memory state. As described in further detail below, in a given verify stage, a sense operation is performed on selected memory cells of a plurality of target memory cells while the power control circuitry 160 applies one or more verify pulses on the selected word line in order to verify whether the selected memory cells are programmed to an assigned memory state. To do so, a sense operation performed in a verify stage determines whether the selected memory cells' threshold voltages have increased to above the verify voltage level Vv associated with the memory state and the verify stage. Those target memory cells assigned to memory states different than the associated memory state are not verified during the given verify stage.

Herein, a program-verify operation is an operation performed by circuitry on a memory die during which the circuitry applies a program pulse on a word line and then verifies which of a plurality of memory cells coupled to the word line are programmed in their assigned memory states in response to the program pulse. A program-verify operation includes a combination of a program stage and at least one verify stage that follows the program stage. Additionally, in at least some example configurations, the program-verify operation may include a pre-charge stage at the beginning of the program-verify operation (i.e., before the program stage begins).

Herein, a pre-charge stage is a stage of a program-verify operation that occurs before the program stage. During the pre-charge stage, bit line biasing circuitry selectively biases bit lines to cause memory cells connected to the bit lines and the selected word line that are not yet programmed into their assigned memory states to increase their threshold voltages in response to a program pulse provided in the program stage. Furthermore, during the pre-charge stage, the bit line biasing circuitry may selectively bias, or otherwise control, the voltage or current levels of bit lines connected to other memory cells that are programmed into their assigned memory states such that the memory cells are inhibited from changing their threshold voltages in response to a subsequent program pulse.

A program-verify operation may also include a discharge stage at the end of the program-verify operation (i.e., after a last verify stage of the program-verify operation), during the discharge stage the bit line voltage is discharged down to the initial voltage level (e.g., the cell source voltage level Vcelsrc). Accordingly, an example program-verify operation includes, in sequential order, a pre-charge stage, a program stage, one or more verify stages, and a discharge stage. As each program stage is generally intended to avoid overshooting a desired programming state by injecting small amounts of charge into the cell being programmed followed by one or more verify stages measuring what the resulting programming state is, the program-verify operation may be repeated until the target memory cells have been programmed to respective desired memory states. Otherwise stated, a single program operation to program target memory cells coupled to a selected word line into assigned memory states may include multiple program-verify operations, with each program-verify operation including a program stage followed by one or more verify stages. In this context, within a program operation, one or more verify stages are performed in between consecutive program stages. An example program-verify operation that includes a program stage followed by one or more verify stages is described in further detail below.

In addition, a program stage of a program-verify operation includes the power control circuitry 160 supplying one or more program pulses to the selected word line for that program stage, and a single verify stage of a program-verify operation includes the power control circuitry 160 supplying one or more verify pulses to the selected word line for that single program stage. Accordingly, a program-verify operation may include the power control circuitry 160 supplying a pulse train or a series of voltage pulses to the selected word line, where the pulse train includes one or more program pulses followed by one or more verify pulses. After a last verify pulse of the program-verify operation, the power control circuitry 160 may transition into a next program-verify operation by supplying one or more program pulses, followed by one or more verify pulses. The power control circuitry 160 may proceed in this manner until the program operation concludes. Accordingly, a program operation is complete or concludes when the verify operation portion of the program operation identifies that all of the target memory cells coupled to the selected word line have been programmed to their assigned threshold voltages Vth. As mentioned, the verification operation portion of the program operation verifies or determines that a given target memory cell is finished being programmed when a given verify stage determines that the target memory cell's threshold voltage Vth has increased to above the verify voltage level Vv associated with the memory state to which the target cell is to be programmed.

For some example program-verify operations, all of the target memory cells subject to a program operation are not subject to the same verify stage at the same time. Alternatively, for a single verify stage, only those target memory cells that are assigned to the same memory state are subject to a verify stage. For a single verify stage, target memory cells that are subject to the single verify stage are called selected memory cells or selected target memory cells, and target memory cells that are not subject to the single verify stage are called unselected memory cells or unselected target memory cells. Likewise, for a group of bit lines connected to the target memory cells of a program-verify operation, bit lines connected to the selected memory cells for a single verify stage are called selected bit lines, and bit lines connected to the unselected memory cells for a single verify stage are called unselected bit lines. In this context, a state of the bit line may refer to whether the bit line is selected or unselected. Otherwise stated, a bit line connected to a target memory cell can be in one of two states, selected or unselected.

For each of the verify stages, the power control circuitry 160, or some combination of the power control circuitry 160, the read/write circuitry 144, and the sense blocks 146, may supply voltages at appropriate levels to the selected and unselected word lines and the selected and unselected bit lines in order for a verify stage to be performed for the selected memory cells of the target memory cells subject to the program-verify operation. For clarity, and unless otherwise specified, the combination of the power control circuitry 160, the read/write circuitry 144, and the sense blocks 146 used to bias the selected and unselected word lines and bit lines at appropriate levels during a given memory operation (e.g., a program operation, a verify operation, a program-verify operation, a read operation, a sense operation, or an erase operation) is herein referred to collectively as voltage supply circuitry. Voltage supply circuitry may refer to the power control circuitry 160, the sense block circuitry 146, other circuit components of the read/write circuitry 144, or any combination thereof.

For performance of a verify stage in a block, the voltage supply circuitry may supply a drain select gate bias voltage VSGD on the drain select gate bias line SGD to the control gates of the drain select gate transistors (such as those shown in FIGS. 6-19C) and a source select gate bias voltage VSGS on the source select gate bias line SGS to the control gates of the drain select gate transistors (such as those shown in FIGS. 6-9C) at levels that turn on the drain select gate transistors and the source select gate transistors in response to the voltage supply circuitry supplying voltages at suitable levels on the common source line SL and to the bit lines.

Additionally, the voltage supply circuitry supplies a source line voltage at a cell source voltage level Vcelsrc, otherwise referred to as the cell source voltage Vcelsrc, on the common source line SL. Further, the voltage supply circuitry biases the drain side of the selected bit lines with a high supply voltage VBLC that is higher in magnitude than the cell source voltage Vcelsrc. The difference between the high supply voltage VBLC and the cell source voltage level Vcelsrc may be great enough to allow current to flow from the drain side to the source side of a string that includes a selected target memory cell in the event that the selected target memory cell has a threshold voltage Vth that allows it to conduct a current. During a verify stage, a selected memory cell can be generally characterized as fully conducting, marginally conducting, or non-conducting, depending on the threshold voltage Vth of the selected memory cell. Also, the voltage supply circuitry biases the drain side of the unselected bit lines to the cell source voltage Vcelsrc. By biasing the drain side and the source side of unselected bit lines to the cell source voltage Vcelsrc, the voltage difference between the drain side and source side voltages will not allow current to flow through the NAND string connected to the unselected bit line. Further, the voltage supply circuitry biases the unselected word lines, and in turn the control gates of FGTs coupled to the unselected word lines, to a read voltage Vread. The read voltage is high enough to cause the FGTs coupled to unselected word lines to conduct a current regardless of its threshold voltage Vth. In addition, the voltage supply circuitry biases the selected word line with a control gate reference voltage VCGRV, which may be in the form of one or more verify pulses as previously described. The control gate reference voltage VCGRV may be different for verification of target memory cells of different memory states. For example, the voltage supply circuitry may supply a different control gate reference voltage VCGRV (or a control gate reference voltage VCGRV at different level) when verifying target memory cells programmed to state A than when verifying target memory cells programmed to state B, and so on.

Once the voltage supply circuitry supplies the voltages to the selected and unselected word lines and bit lines, and to the drain select gate transistors, source select gate transistors, drain select gate bias line SGD, and source select gate bias line SGS, a sense block can perform a sense operation that identifies whether a selected target memory cell is conducting, and in turn sufficiently programmed. Further details of a sense operation performed during an associated verify stage are described in further detail below.

A read operation is an operation that identifies the memory states of target memory cells of a page coupled to a selected word line. As previously described, the threshold voltage Vth of a memory cell may identify the data value of the data it is storing. Accordingly, in order to determine the memory stages, the read operation determines whether the target memory cells conduct at a specific threshold voltages Vth applied to the selected word line. To determine the memory states during a read operation, the sense blocks 146 may be configured to perform a sense operation that senses whether current is flowing through the bit lines connected to the target memory cells of the page. The voltage supply circuitry may supply voltages on the selected and unselected word lines at appropriate levels that cause current to flow or not to flow based on the threshold voltage Vth of the target memory cells. The level of the voltage supplied to the selected word lines may vary depending on the memory states of the target memory cells.

The voltage supply circuitry may also bias the bit lines so that the high supply voltage VBLC is applied to the drain side of the bit lines and the cell source voltage Vcelsrc is applied to the source side of the bit lines to allow for the current flow, provided that the threshold voltage Vth of the selected memory cell allows for it. For some example read configurations, the sense block 146 can perform a sense operation for fewer than all of the memory cells of a page. For such configurations, the target memory cells of the page that are subject to and/or that are selected for a given sense operation are referred to as selected memory cells or selected target memory cells. Conversely, the target memory cells of the page that are not subject to and/or that are not selected for the sense operation are referred to as unselected memory cells. Accordingly, bit lines connected to selected target memory cells are referred to as selected bit lines, and bit lines connected to unselected target memory cells are referred to as unselected bit lines. In this context, a state of the bit line may refer to whether the bit line is selected or unselected. Otherwise stated, a bit line can be in one of two states, selected or unselected. The voltage supply circuitry can supply the voltages to the selected and unselected word lines and the selected and unselected bit lines at levels in various combinations, in various sequences, and/or over various sense operations in order determine the threshold voltages of the target memory cells so that the data values of the data that the target memory cells are storing can be determined.

In addition, as described in further detail below, a read operation to read data from a plurality of target memory cells coupled to a selected word line may include a plurality of stages, including one or more read stages and a discharge stage at the end of a last read stage. A read stage is a stage of a read operation that identifies which of the target memory cells coupled to the selected word line are programmed in a memory state associated with the read stage. Circuitry involved in the read operation performs a sense operation in each of the read stages to determine the memory states, and in turn the logic or data values of the plurality of target memory cells. As the target memory cells may be programmed in different memory states, each read stage is associated with a different one of the memory states in which the target memory cells may be programmed. During a read operation, a given read stage is performed to determine which of the target memory cells are programmed in the memory state associated with the given read stage.

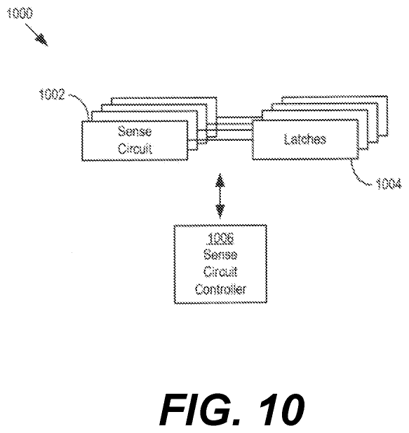

FIG. 10 is a block diagram of an example configuration of a sense block 1000 configured to perform a sense operation. The sense block 1000 may be representative of one of the sense blocks 146(1) to 146(p) of FIG. 2B. The sense block 1000 may include a plurality of sense circuits 1002 and a plurality of sets of latches 1004. Each sense circuit (also referred to as a sense amplifier circuit) 1002 may be associated with a respective one of the latches 1004. That is, each sense circuit 1002 may be configured to communicate with and/or perform a sense operation using data and/or storing data into its associated latches set 1004. Additionally, the sense block 1000 may include a sense circuit controller 1006 that is configured to control operation of the sense circuits 1002 and the sets of latches 1004 of the sense block 1000. As described in further detail below, the sense circuit controller 106 may control operation of the sense circuits 1002 and the latches 1004 by outputting control signals to terminals of the sense circuits 1002 and the latches 1004. Additionally, the sense circuit controller 1006 may communicate with and/or may be a part of the control logic 154. The sense circuit controller 1006 may be implemented in hardware, or a combination of hardware and software. For example, the sense circuit controller 1006 may include a processor that executes computer instructions stored in memory to perform at least some of its functions.

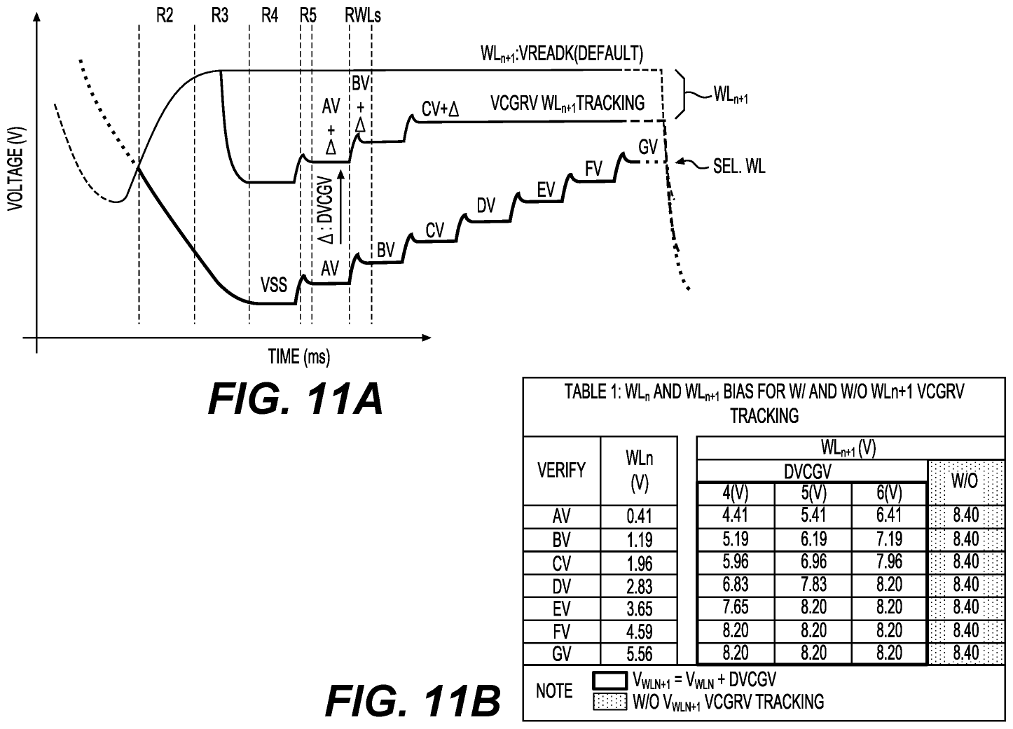

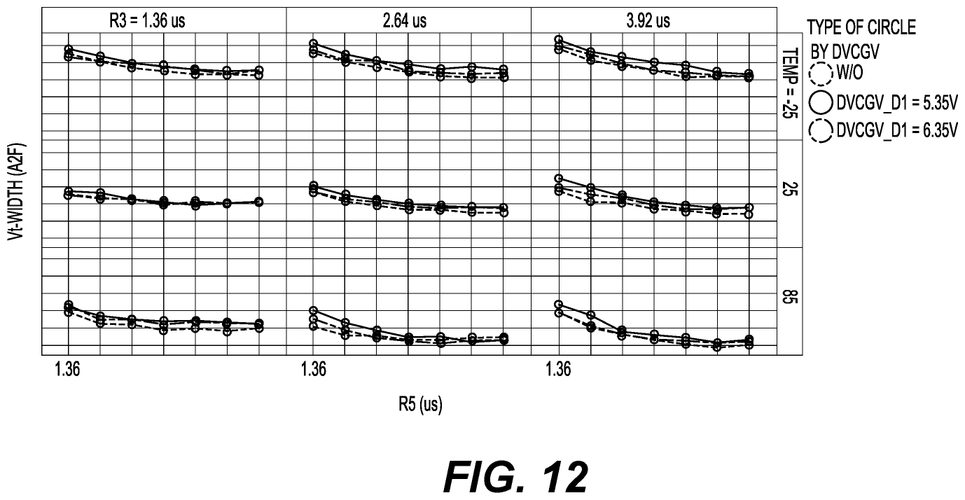

As previously discussed, it is desirable to improve programming performance or speed by reducing verify time during or after programming. Yet, it is still important to minimize any penalty from threshold voltage Vth margin degradation resulting from such a reduction in verify time. Referring to FIG. 11A, during a conventional program-verify operation, a neighbor word line (e.g., a drain side neighbor word line WLn+1 disposed on a drain side of the selected word line WLn) initially is set to a voltage Vpass from the program operation (to allow electrical current to flow through the string of memory cells during the programming) when a program voltage VPGM is applied to the selected word line WLn. The voltage on WLn+1 first ramps down towards a steady state voltage Vss, and then ramps up to a default read pass voltage Vreadk to ensure WLn+1 is conducting (waveform indicated as WLn+1: VREADK(DEFAULT)). In comparison, a setup time of the selected word line WLn is improved by reducing the coupling capacitance from the adjacent or neighbor word line (e.g., the drain side neighbor word line WLn+1) by using a WLn+1 waveform that tracks the voltage of the selected word line WLn during program verify (the selected word line WLn voltage waveform is indicated as SEL. WL and the voltage waveform of the neighbor word line (e.g., WLn+1) indicated as VCGRV WLn+1 TRACKING). The program-verify operation can include a bit line pre-charge period (P-clock), a program period (PD-clock), a first verify period (R-clock) which can include a plurality of predetermined time periods (e.g., a first period R1, a second period R2, a third period R3, a fourth period R4, a fifth period R5, and a sixth period R6), a second verify period (RWL-clock) and a discharging period (RR-clock). As discussed herein, the memory cells connected to the selected word line WLn (e.g., WL0 of FIG. 7) are programmed before those connected to the drain side neighbor word line WLn+1 (e.g., WL1 of FIG. 7); however, it should be appreciated that if programming is done in an opposite order, the neighbor word line discussed herein could instead be a neighbor word line disposed on a source side of the selected word line WLn. Thus, any word lines that might be capacitively coupled to the selected word line WLn are contemplated herein.

Still referring to FIG. 11A, the voltage applied to the neighbor word line (e.g., the drain side neighbor word line WLn+1 disposed on a drain side of the selected word line WLn) is offset from the voltage applied to the selected word line WLn by an offset or delta control gate reference voltage (DVCGV) during verify stages for some of the data states (e.g., state A, state B, and state C or higher states). So, the neighbor word line (e.g., WLn+1) is biased to VCGRV+DVCGV. Then the voltage applied to the neighbor word line (e.g., WLn+1) can be ramped in a similar manner as the voltage applied to the selected word line WLn during stages of the verify operation. Voltages lower than the default read pass voltage VREADK can be applied on the neighbor word line because the neighbor word line is in the erase state during the program and verify of the selected word line WLn. FIG. 11B shows a table of the biases or voltages applied to the selected word line WLn and neighbor word line (e.g., WLn+1) with and without tracking of the control gate reference voltage VCGRV by the neighbor word line (i.e., a control gate reference voltage VCGRV tracking mode).

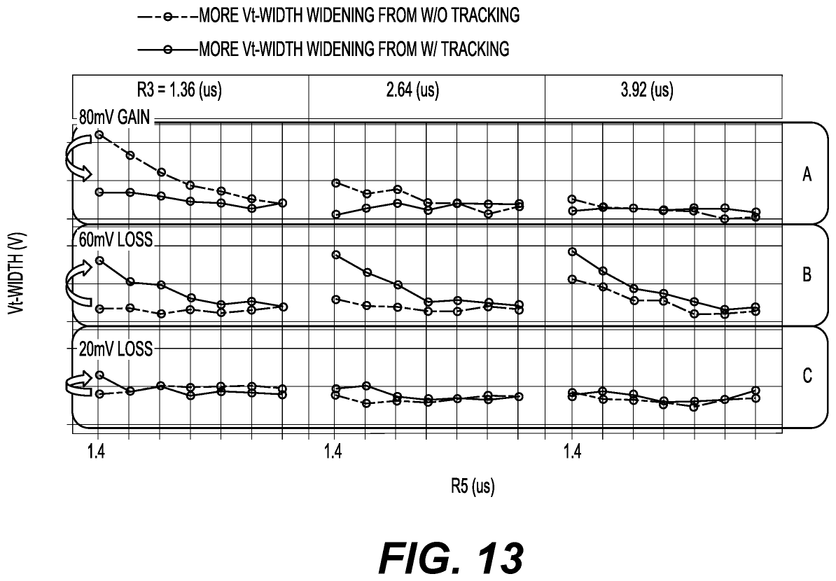

FIG. 12 illustrates widths of threshold voltage (Vt) distributions with and without tracking of the control gate reference voltage VCGRV at a low temperature (−25 degrees Celsius), a regular temperature (25 degrees Celsius), and a high temperature (85 degrees Celsius) for various lengths of time periods (third period R3, fifth period R5) of a verify stage of the program-verify operation. As shown, while such tracking by the neighbor word line is intended to be helpful, the data illustrated shows that no significant improvement is provided by the VCGRV tracking mode. The threshold voltage Vth distribution width is collected when shortening R3 and R5 time periods from default settings of these time periods. As discussed in more detail below, one reason why the tracking does not improve the timing margin is that some data states (e.g., state A) benefit from the tracking, but some states do not (e.g., state B, state C, etc.). FIG. 13 shows a threshold voltage distribution width for state A, state B, and state C for various lengths of the plurality of time periods of a verify stage of the program-verify operation. As shown, the threshold voltage Vth distribution width for state A is improved with shorter verify timing when the tracking is enabled. State B actually has narrower threshold voltage Vth distribution width with the tracking mode disabled. For state C and higher states (e.g., state D, state E, etc.) the bias applied on the neighbor word line (e.g., WLn+1) is closer to the default read pass voltage Vreadk, therefore the threshold voltage Vth distribution width widening behavior is similar when tracking is enabled or not for shortened timing (e.g., R3). It turns out potential improvements occur at “R-clock” which is the first verified state in a given program-verify operation (pvfy). The “RWL-clocks” where later states are verified have no benefit.

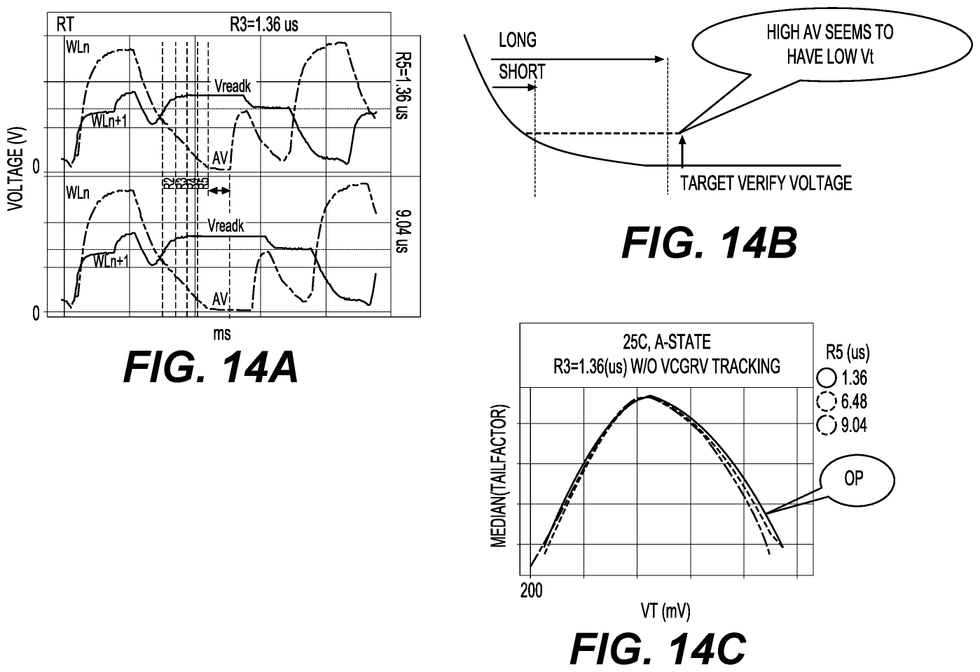

FIG. 14A shows a verify voltage waveform applied to the selected word line WLn and neighbor word line (e.g., WLn+1) for the state A without tracking. As discussed, without tracking during the verify stages of the program-verify operation, the A-state or state A is not prevented from widening of the threshold voltage Vth distribution as timing is reduced. Such behavior is due to the voltage of the selected word line WLn for the state A (i.e., A-state verify voltage (AV)) on the selected word line WLn not being able to ramp down to the target verify voltage when time periods R3 and R5 are very short as shown FIG. 14B. Thus, the threshold voltage Vt or Vth of the selected memory cells (i.e., those memory cells connected to the selected word line WLn) will appear to be lower than expected and those cells will experience extra program pulses which leads to over programming (OP) shown in FIG. 14C which shows a median tailfactor plotted versus the threshold voltage Vth without tracking.

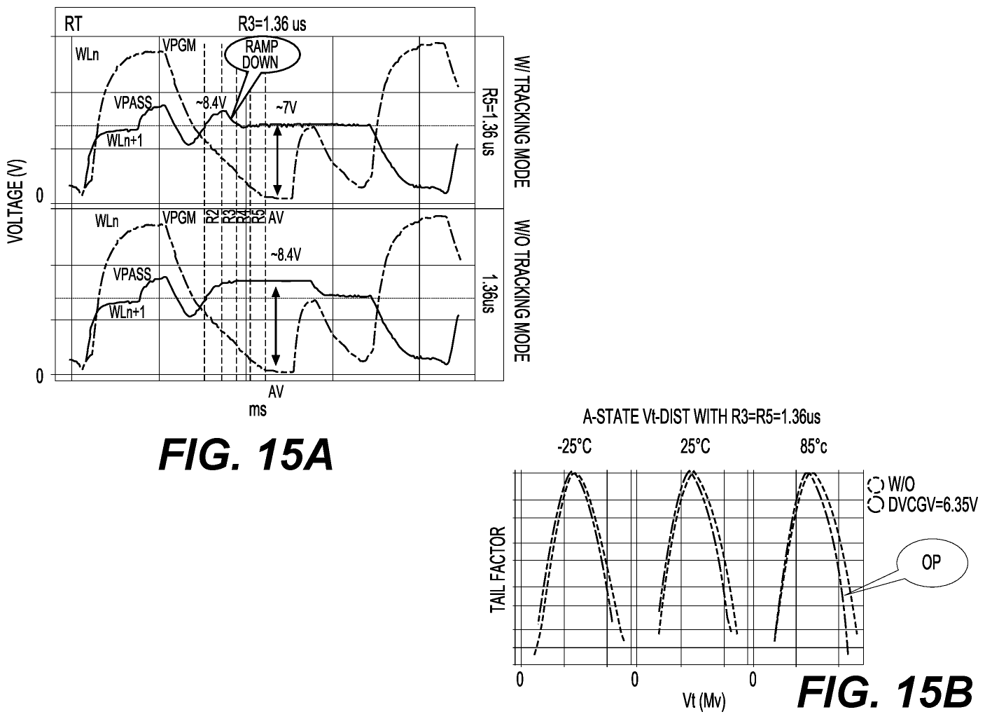

FIG. 15A shows a verify voltage waveform applied to the selected word line WLn and neighbor word line for the state A with and without tracking. As shown, a primary benefit from the tracking mode occurs at the R3 clock or time period. During this time the voltage on the neighbor word line ramps down, which assists the voltage of the selected word line WLn to settle. Without tracking, the voltage on the neighbor word line stays at 8.4V and cannot assist the voltage of the selected word line WLn to settle. When the VCGRV tracking is enabled, the voltage of the selected word line WLn reaches the target level (e.g., AV) more quickly, and there is less widening of threshold voltage Vth distribution width. When VCGRV tracking is disabled, the voltage of the selected word line WLn cannot reach the target level, and there is more widening of the threshold voltage Vth distribution as shown in FIG. 15B, which shows a tailfactor plotted versus a threshold voltage Vth of the state A with and without the control gate reference voltage VCGRV tracking mode at different temperatures. The verify levels are adjusted when tracking mode is enabled so that the threshold voltage Vth distributions exactly match the case without the VCGRV tracking as long as timing settings are long and relaxed. Thus, all lower/upper tail movements of the threshold voltage Vth distribution are due to squeezed timing (reduced timing settings for R3 and R5 time periods).

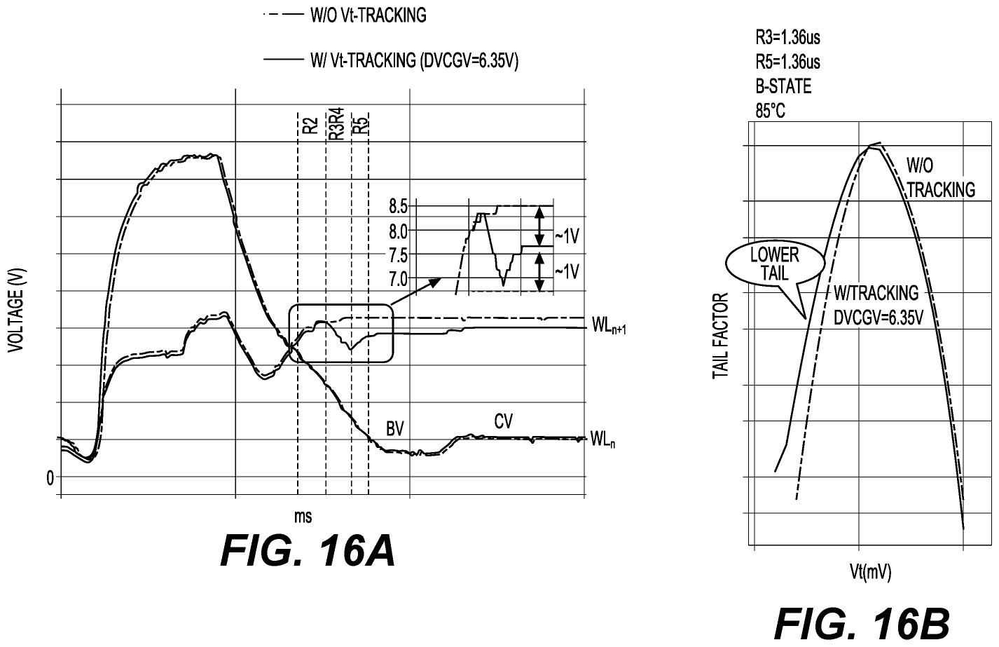

FIG. 16A shows a verify voltage waveform applied to the selected word line WLn and neighbor word line for state B and state C with and without tracking. With the tracking enabled, the voltage of the neighbor word line (e.g., the drain side neighbor word line WLn+1 disposed on a drain side of the selected word line WLn) does ramp down in the R3-R4 time periods of the verify stage and provides some capacitive coupling assist to voltage of the selected word line WLn. However, since both the voltage of the selected word line WLn and the voltage of the neighbor word line ramp down during the R3 time period, the voltage on the neighbor word line can undershoot even at very short R3. However, as the voltage of the neighbor word line recovers from the undershoot, it is fighting against the coupling from voltage of the selected word line WLn which is ramping down. This means with short timing settings the voltage of the neighbor word line is still lower than the target level. If the voltage of the neighbor word line is lower than expected, the cell threshold voltage Vth appears higher than it actually is. In this case the memory cells experience program-inhibit too early, leading to the extra lower tail as shown in FIG. 16B, which shows the tailfactor plotted versus the threshold voltage Vth of the state B at 85 degrees Celsius with and without tracking.

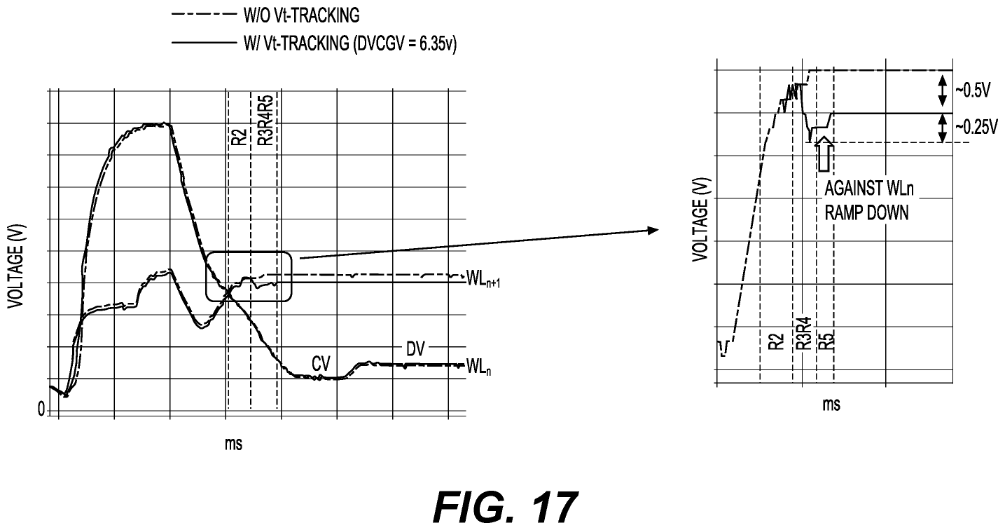

FIG. 17 shows a verify voltage waveform applied to the selected word line WLn and neighbor word line for state C and state D with and without tracking. As shown, the results for state C is qualitatively similar to that of the state B shown in FIG. 16A. However, the neighbor word line (e.g., WLn+1) voltage waveform transitions are smaller in magnitude so deviations from the conventional case or without tracking are much smaller.

As discussed, the apparatus includes a plurality of selected memory cells coupled to a selected word line WLn and each storing a threshold voltage representative of a selected cell data programmed in a program-verify operation. The apparatus also includes a plurality of unselected memory cells coupled to a neighbor word line disposed adjacent the selected word line WLn. Certain “bad” aspects of the implementation of the tracking mode may be the reason that the state B is worse when the tracking mode is enabled. Also, certain “good” aspects from state A verify could be enhanced. Thus, it can be advantageous to modify the tracking mode in order to avoid the overshoot\undershoot during ramping, align the ramping directions of the voltages of the selected word line WLn and the neighbor word line, and improve programming time without much (if any) penalty from Vt-margin loss (e.g., width of threshold voltage Vth distributions).

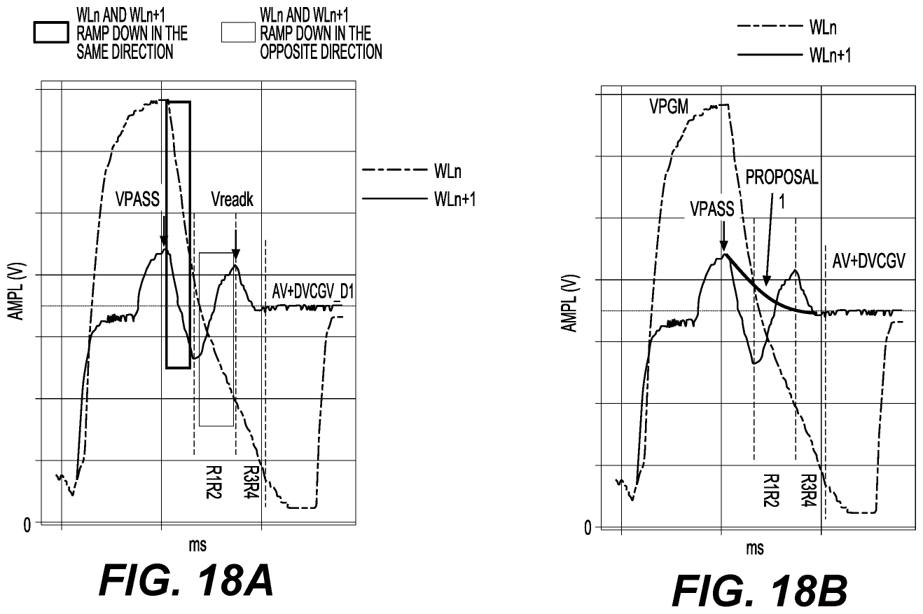

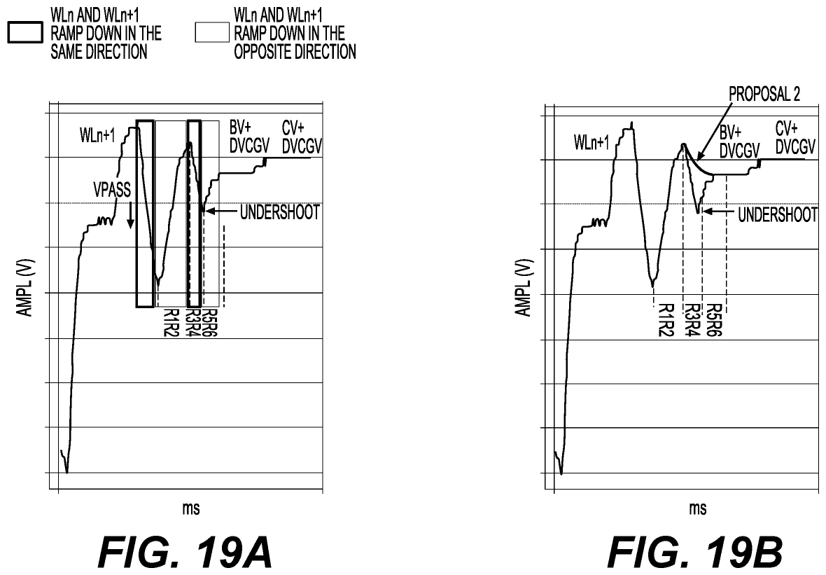

FIGS. 18A and 18B show a verify voltage waveform applied to the selected word line WLn and neighbor word line (e.g., WLn+1) with the control gate reference voltage tracking mode and with a first modified control gate reference voltage tracking mode (Proposal 1). Referring first to FIG. 18A, it can be seen that from a pass voltage VPASS to a first time period R1, the voltage of the neighbor word line (e.g., the drain side neighbor word line WLn+1 disposed on a drain side of the selected word line WLn) and voltage of the selected word line WLn are ramping down in the same direction, which can help the selected word line WLn reach the target setting quickly. From the first time period R1 to a third time period R3, the voltage of the neighbor word line (e.g., WLn+1) is ramping up to a default read pass voltage Vreadk, but the voltage of the selected word line WLn is continuously ramping down. Then this ramping-up of the voltage on the neighbor word line will make the voltage of the selected word line WLn reach the target setting slowly (due to capacitive coupling).

Consequently, the apparatus (e.g., memory system 100) disclosed herein includes a control circuit (e.g., controller 102, peripheral circuitry 152) coupled to the plurality of selected and the plurality of unselected memory cells and configured to ramp from at least one initial voltage applied to the neighbor word line (e.g., WLn+1) directly to a target neighbor verify voltage (e.g., AV+DVCGV, BV+DVCGV, etc.) without exceeding or falling below the target neighbor verify voltage. Therefore, with the first modified control gate reference voltage tracking mode, such ramping by the control circuit assists the selected word line WLn reach at least one verify reference voltage (e.g., Vv discussed herein, such as AV for state A) used in verifying the threshold voltage Vth of each of the plurality of selected memory cells during at least one verify stage of the program-verify operation following a program stage of the program-verify operation.

Again, the threshold voltage Vth of each of the plurality of selected memory cells is within a common range of threshold voltages Vth defining a plurality of data states associated with threshold voltage Vth distributions of the threshold voltage Vth. For the VCGRV tracking or tracking mode, the at least one verify reference voltage includes a plurality of verify reference voltages each corresponding to one of the plurality of data states (e.g., AV for state A, BV for state B, etc. as shown in FIG. 11A). As discussed, the at least one verify stage can include a sequence of a plurality of verify stages. Therefore, the control circuit is further configured to select and apply one of the plurality of verify reference voltages to the selected word line WLn based on which of the plurality of data states is being verified during each of the plurality of verify stages. The control circuit simultaneously adjusts the target neighbor verify voltage applied to the neighbor word line according to the one of the plurality of verify reference voltages applied to the selected word line WLn for each of the plurality of verify stages (e.g., AV+DVCGV, BV+DVCGV, etc.).

According to an aspect, the at least one initial voltage applied to the neighbor word line includes a pass voltage VPASS causing the plurality of unselected memory cells to conduct electricity during the program stage. Again, each of the plurality of verify stages includes a plurality of predetermined time periods (R1, R2, R3, R4, R5, etc.). So, as best shown in FIG. 18B, the control circuit is further configured to apply the pass voltage VPASS to the neighbor word line while applying a program voltage VPGM to the selected word line WLn during the program operation before a first period R1 of the plurality of predetermined time periods R1, R2, R3, R4, R5, R6. The control circuit is also configured to ramp the pass voltage VPASS applied to the neighbor word line beginning before the first period R1 of the plurality of predetermined time periods directly to the target neighbor verify voltage over a second period R2 and a third period R3 and a fourth period R4 of the plurality of predetermined time periods without exceeding or falling below the target neighbor verify voltage to define a first ramped voltage waveform (labeled Proposal 1). In other words, the voltage of the neighbor word line is ramped from VPASS directly down to the target setting or target neighbor verify voltage (e.g., before state A verify, the voltage of the neighbor word line will be at AV+DVCGV_D1). Therefore ramping direction of the voltage on the neighbor word line (e.g., WLn+1) will be same as the voltage of the selected word line WLn before verify from VPASS to the fifth period R5.

FIGS. 19A and 19B show a verify voltage waveform applied to the selected word line WLn and neighbor word line (e.g., WLn+1) with the control gate reference voltage VCGRV tracking mode and with a second modified control gate reference voltage tracking mode (Proposal 2). Referring first to FIG. 19A, it can be seen that from the third period R3 to the fifth period R5, the voltage of the neighbor word line (e.g., the drain side neighbor word line WLn+1 disposed on a drain side of the selected word line WLn) and the voltage of the selected word line WLn are ramping down in the same direction, which can help the selected word line WLn reach the target setting quickly. Also the voltage of the neighbor word line includes an undershoot as shown. For state B and higher states, from the fifth period R5 to the sixth period R6, the voltage of the neighbor word line is ramping up from the undershoot voltage which is in the opposite ramping direction of voltage of the selected word line WLn.

Thus, according to an aspect and shown in FIG. 19B, the control circuit is further configured to apply the default read pass voltage VPASS to the neighbor word line (e.g., WLn+1) after the program operation after the first period R1 and the second period R2 of the plurality of predetermined time periods. The control circuit is also configured to ramp the pass voltage VPASS applied to the neighbor word line beginning after the first period R1 and the second period R2 of the plurality of predetermined time periods directly to the target neighbor verify voltage over the third period R3 and the fourth period R4 and into a fifth period R5 of the plurality of predetermined time periods without exceeding or falling below the target neighbor verify voltage to define a second ramped voltage waveform (labeled Proposal 2). So, with the second modified control gate reference voltage tracking mode, before the third period R3, the voltage of the neighbor word line follows the conventional tracking mode described above and from the third period R3 the voltage of the neighbor word line doesn't ramp down to the undershoot voltage and instead, ramps down to the target neighbor verify voltage (e.g., BV+DVCGV_D1 directly). Thus, with the second ramped voltage waveform, the overshoot of the voltage of the neighbor word line after the third period R3 is avoided and the opposite ramping direction of the voltage of the neighbor word line is removed allowing the timing between the third period R3 and sixth period R6 to be reduced since the selected word line WLn can more quickly reach the verify reference voltage used in verifying the threshold voltage Vth of each of the plurality of selected memory cells.

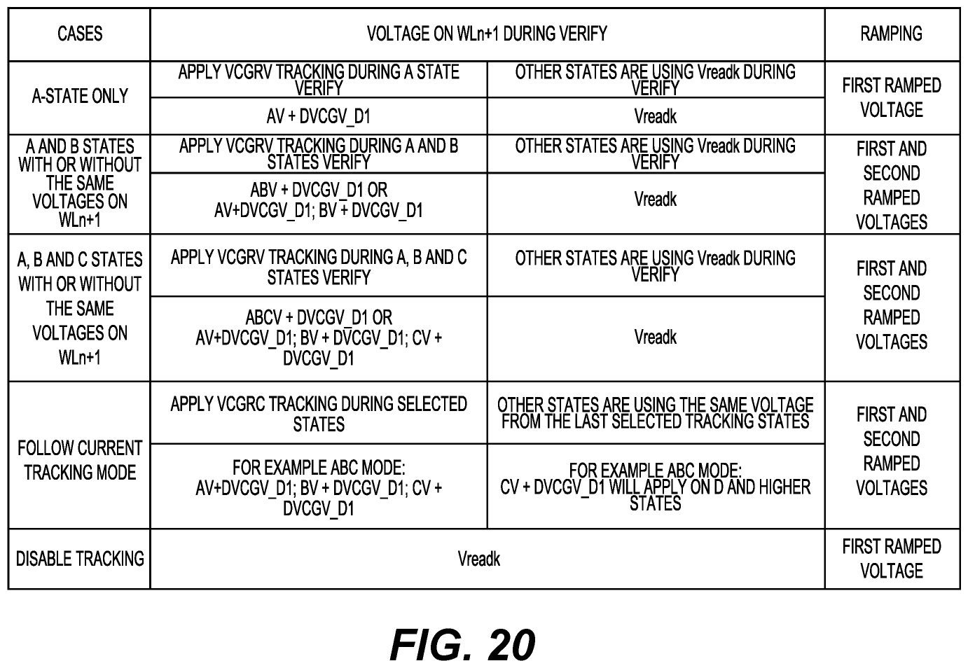

FIG. 20 shows a table with an exemplary implementation of the with the first and second modified control gate reference voltage tracking modes (Proposal 1 and Proposal 2). As discussed above, it can be seen that lower states (especially state A) can have improved program time without threshold voltage Vth margin degradation as compared to higher states from the VCGRV tracking mode. Therefore, the exemplary implementation of the improved tracking mode employing the first and second ramped voltages or first and second voltage waveforms focuses on scenarios for these lower states.

The plurality of data states includes a plurality of lower states (e.g., state A, state B, state C) associated with lower threshold voltages Vth of the common range of threshold voltages Vth and a plurality of upper states (state D, state E, etc.) associated with upper threshold voltages Vth of the common range of threshold voltages Vth that are larger in magnitude than the lower threshold voltages Vth. Thus, the control circuit is further configured to apply at least one of the first ramped voltage waveform and the second ramped voltage waveform to the neighbor word line in response to one or more of the plurality of lower states of the plurality of data states being verified during one of the plurality of verify stages. The control circuit is also configured to apply the default read pass voltage Vreadk to the neighbor word line (e.g., the drain side neighbor word line WLn+1 disposed on a drain side of the selected word line WLn) in response to one or more of the plurality of upper states of the plurality of data states being verified during one of the plurality of verify stages.

As discussed above, the plurality of data states can, for example, include an erased state (state Er) and a first data state (state A) and a second data state (state B) and a third data state (state C) and a fourth data state (state D) and a fifth data state (state E) and a sixth data state (state F) and a seventh data state (state G) each associated with different increasing threshold voltage Vth distributions of the threshold voltage Vth in the common range of threshold voltages Vth. So, as shown in FIG. 20, the control circuit is further configured to apply at least one of the first ramped voltage waveform and the second ramped voltage waveform to the neighbor word line (e.g., WLn+1) in response to at least one of the first data state (state A) and the second data state (state B) and the third data state (state C) of the plurality of data states being verified during one of the plurality of verify stages. The control circuit is also configured to apply the default read pass voltage Vreadk to the neighbor word line in response to at least one of the third data state (state C) and the fourth data state (state D) and the fifth data state (state E) and the sixth data state (state F) and the seventh data state (state G) of the plurality of data states being verified during one of the plurality of verify stages.

Even without the VCGRV tracking mode, a standard or default verify operation can also benefit from the use of the first and second voltage waveforms. The at least one initial voltage applied to the neighbor word line is a pass voltage VPASS causing the plurality of unselected memory cells to conduct electricity during the program stage. So, the control circuit is further configured to select and apply one of the plurality of verify reference voltages to the selected word line WLn based on which of the plurality of data states is being verified during each of the plurality of verify stages. The control circuit is also configured to simultaneously ramp the pass voltage VPASS applied to the neighbor word line beginning before a first period R1 of the plurality of predetermined time periods directly to a default read pass voltage Vreadk over a second period R2 and a third period R3 and a fourth period R4 of the plurality of predetermined time periods without exceeding or falling below the default read pass voltage Vreadk. Again, the default read pass voltage Vreadk causes the plurality of unselected memory cells to conduct electricity during each of the plurality of verify stages.

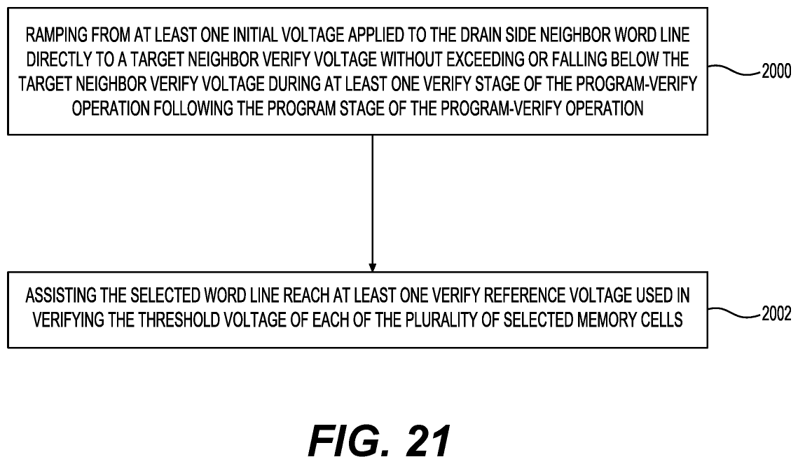

As best shown in FIG. 21, a method of operating a memory apparatus is also provided. Again, the memory apparatus includes a plurality of selected memory cells coupled to a selected word line WLn. Each of the plurality of selected memory cells stores a threshold voltage Vth representative of a selected cell data programmed in a program-verify operation. A plurality of unselected memory cells are coupled to a neighbor word line (e.g., the drain side neighbor word line WLn+1 disposed on a drain side of the selected word line WLn). The method includes the step of 2000 ramping from at least one initial voltage applied to the neighbor word line directly to a target neighbor verify voltage (e.g., AV+DVCGV, BV+DVCGV, etc.) without exceeding or falling below the target neighbor verify voltage during at least one verify stage of the program-verify operation following the program stage of the program-verify operation. The method also includes the step of 2002 assisting the selected word line WLn reach at least one verify reference voltage (e.g., AV for state A, BV for state B, etc.) used in verifying the threshold voltage Vth of each of the plurality of selected memory cells.

As discussed, the threshold voltage Vth of each of the plurality of selected memory cells can be within a common range of threshold voltages Vth defining a plurality of data states associated with threshold voltage Vth distributions of the threshold voltage Vth. Also, the at least one verify reference voltage includes a plurality of verify reference voltages each corresponding to one of the plurality of data states and the at least one verify stage includes a sequence of a plurality of verify stages. So, the method further includes the step of selecting and applying one of the plurality of verify reference voltages to the selected word line WLn based on which of the plurality of data states is being verified during each of the plurality of verify stages. The method also includes the step of simultaneously adjusting the target neighbor verify voltage applied to the neighbor word line according to the one of the plurality of verify reference voltages applied to the selected word line WLn for each of the plurality of verify stages.

According to an aspect and as discussed above, the at least one initial voltage applied to the neighbor word can be a pass voltage VPASS causing the plurality of unselected memory cells to conduct electricity during the program stage. In addition, each of the plurality of verify stages includes a plurality of predetermined time periods (e.g., R1, R2, R3, R4, R5, etc.). Thus, the method further includes the step of applying the pass voltage VPASS to the neighbor word line while applying a program voltage VPGM to the selected word line WLn during the program operation before a first period R1 of the plurality of predetermined time periods. The next step of the method is ramping the pass voltage VPASS applied to the neighbor word line beginning before the first period R1 of the plurality of predetermined time periods directly to the target neighbor verify voltage (e.g., AV+DVCGV, BV+DVCGV, etc.) over a second period R2 and a third period R3 and a fourth period R4 of the plurality of predetermined time periods without exceeding or falling below the target neighbor verify voltage to define a first ramped voltage waveform (Proposal 1).

According to another aspect and as discussed above, the at least one initial voltage applied to the neighbor word line can be a default read pass voltage Vreadk causing the plurality of unselected memory cells to conduct electricity during the plurality of verify stages. Each of the plurality of verify stages includes the plurality of predetermined time periods. Therefore, the method further includes the step of applying the default read pass voltage Vreadk to the neighbor word line after the program operation after the first period R1 and the second period R2 of the plurality of predetermined time periods. Next, ramping the pass voltage VPASS applied to the neighbor word line beginning after the first period R1 and the second period R2 of the plurality of predetermined time periods directly to the target neighbor verify voltage over the third period R3 and the fourth period R4 and into a fifth period R5 of the plurality of predetermined time periods without exceeding or falling below the target neighbor verify voltage to define a second ramped voltage waveform (Proposal 2).

In addition, the plurality of data states includes a plurality of lower states associated with lower threshold voltages Vth of the common range of threshold voltages Vth and a plurality of upper states associated with upper threshold voltages of the common range of threshold voltages Vth being larger in magnitude than the lower threshold voltages Vth. So, the method further includes the step of applying at least one of the first ramped voltage waveform (Proposal 1) and the second ramped voltage waveform (Proposal 2) to the neighbor word line (e.g., WLn+1) in response to one or more of the plurality of lower states of the plurality of data states being verified during one of the plurality of verify stages. The method continues by applying the default read pass voltage Vreadk to the neighbor word line in response to one or more of the plurality of upper states of the plurality of data states being verified during one of the plurality of verify stages. In more detail, the plurality of data states includes an erased state (e.g., state Er) and a first data state (e.g., state A) and a second data state (e.g., state B) and a third data state (e.g., state C) and a fourth data state (e.g., state D) and a fifth data state (e.g., state E) and a sixth data state (e.g., state F) and a seventh data state (e.g., state G) each associated with different increasing threshold voltage Vth distributions of the threshold voltage Vth in the common range of threshold voltages Vth. Consequently, the method further includes the step of applying at least one of the first ramped voltage waveform and the second ramped voltage waveform to the neighbor word line in response to at least one of the first data state and the second data state and the third data state of the plurality of data states being verified during one of the plurality of verify stages. The next step of the method is applying the default read pass voltage Vreadk to the neighbor word line in response to at least one of the third data state and the fourth data state and the fifth data state and the sixth data state and the seventh data state of the plurality of data states being verified during one of the plurality of verify stages.

Again, the threshold voltage Vth of each of the plurality of selected memory cells is within a common range of threshold voltages Vth defining a plurality of data states associated with threshold voltage Vth distributions of the threshold voltage Vth. The at least one verify reference voltage includes a plurality of verify reference voltages each corresponding to one of the plurality of data states. The at least one verify stage includes a sequence of a plurality of verify stages. The at least one initial voltage applied to the neighbor word line is a pass voltage VPASS causing the plurality of unselected memory cells to conduct electricity during the program operation. Each of the plurality of verify stages includes a plurality of predetermined time periods (e.g., R1, R2, R3, R4, R5, etc.). The method further includes the step of selecting and applying one of the plurality of verify reference voltages to the selected word line WLn based on which of the plurality of data states is being verified during each of the plurality of verify stages. The method also includes the step of simultaneously ramping the pass voltage VPASS applied to the neighbor word line beginning before a first period R1 of the plurality of predetermined time periods directly to a default read pass voltage Vreadk over a second period R2 and a third period R3 and a fourth period R4 of the plurality of predetermined time periods without exceeding or falling below the default read pass voltage Vreadk (the default read pass voltage Vreadk causes the plurality of unselected memory cells to conduct electricity during the verify operation).

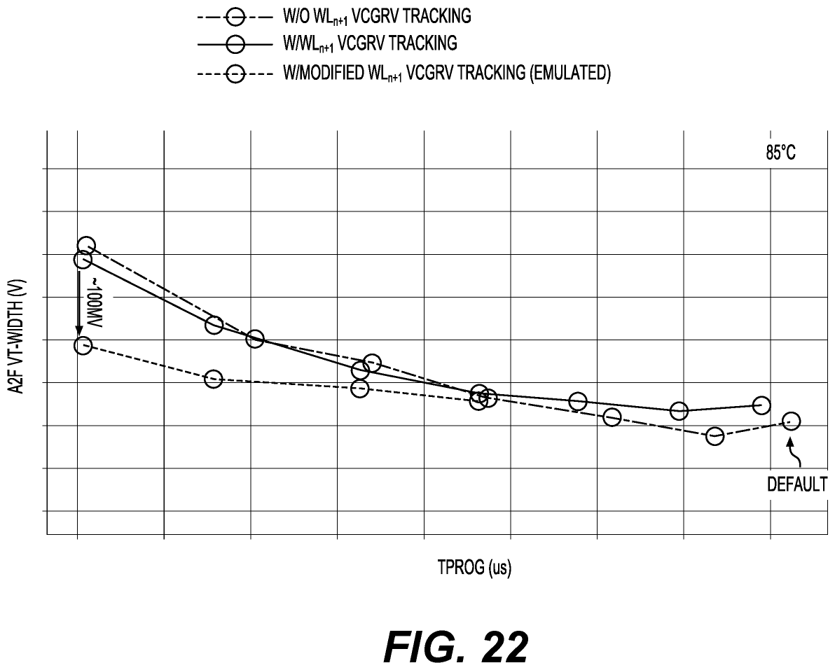

FIG. 22 shows threshold voltage Vth distribution width plotted versus a program time for the non-volatile memory system (e.g., system 100) with the first and second modified control gate reference voltage VCGRV tracking modes for the neighbor word line (e.g., the drain side neighbor word line WLn+1 disposed on a drain side of the selected word line WLn) compared to the control gate reference voltage VCGRV tracking mode and without the control gate reference voltage VCGRV tracking mode according to aspects of the disclosure. In contrast to the control gate reference voltage VCGRV tracking mode (non-modified) implementation that does not appreciably improve the trade-off between threshold voltage Vth distribution width and programming time, the disclosed memory apparatus or system and method steps disclosed herein with the first and second modified control gate reference voltage VCGRV tracking modes demonstrate at least 100 mV threshold voltage Vth distribution width reduction while providing improved timing during program-verify operations.

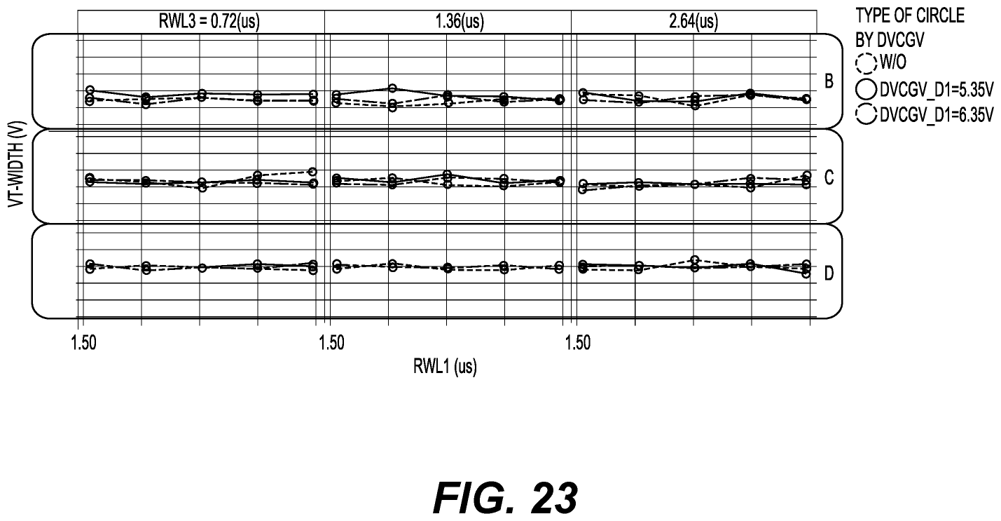

Additional testing data is shown in FIGS. 23-29. Specifically, in FIG. 23, a threshold voltage Vth distribution width for state B, state C, and state D during a time period (i.e., the “RWL-clock”) after the plurality of time periods discussed above (i.e., after R1, R2, R3, R4, R5, and R6) for various RWL1 and RWL3 time periods. No threshold voltage Vth distribution width differences are apparent between the disabling and enabling of the VCGRV tracking mode, likely because the modulation of the selected word line WLn voltage ramping from the neighbor word line (e.g., the drain side neighbor word line WLn+1 disposed on a drain side of the selected word line WLn) during RWL clock verify is much less than during R clock verify (i.e., during the R1, R2, R3, R4, R5, and R6 time periods of the at least one verify stage).

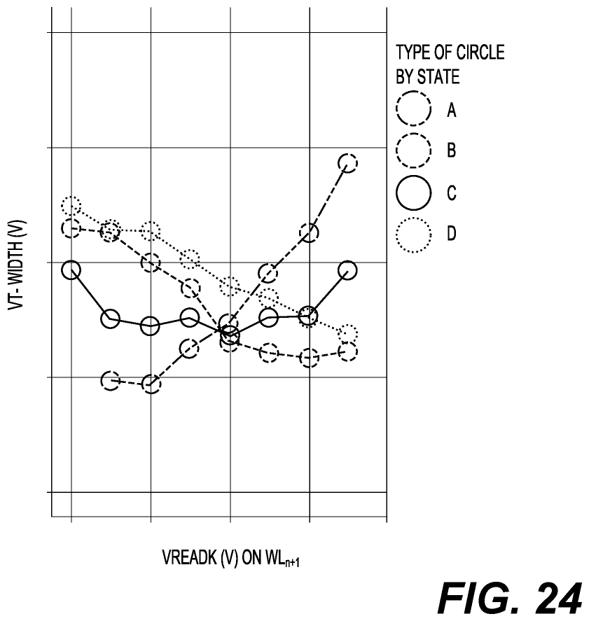

Referring to FIG. 24, a plot is provided showing the threshold voltage Vth distribution width versus the default read pass voltage Vreadk for each of the first, second, third, and fourth data states (state A, state B, state C, and state D). As shown in FIG. 23, there is not a large benefit of VCGRV tracking mode during RWL clocks. However, it is shown in FIG. 24 that it is advantageous to step up the voltage of the neighbor word line (e.g., WLn+1) during the RWL clocks. The reason is that at R-clock, different data states may have improved operation or performance with different biases or voltage of the neighbor word line. So, for consistent biasing, these state-dependent voltages must also be matched during the RWL clocks. As shown, the first data state (state A or A-State) operates better with a comparatively lower default read pass voltage Vreadk. The second state (B state) and higher states operates better with a comparatively higher default read pass voltage Vreadk.

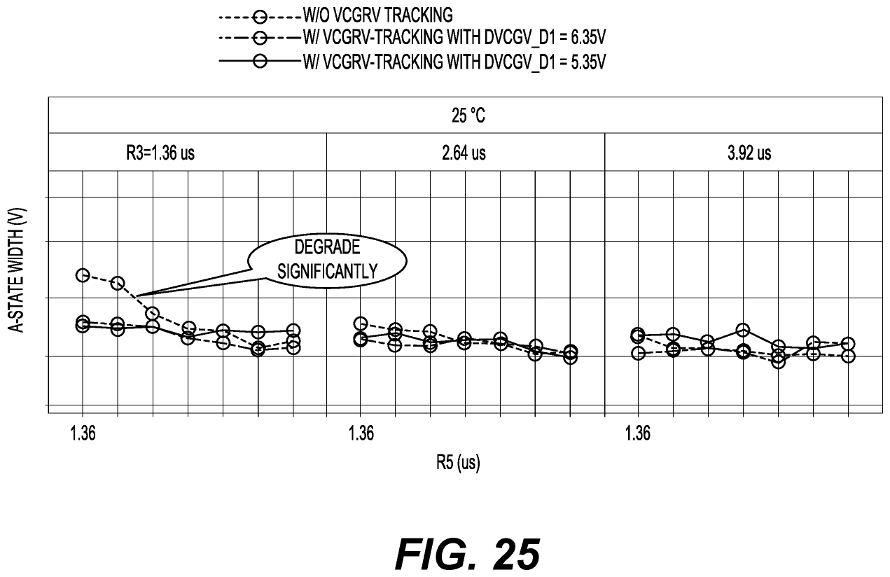

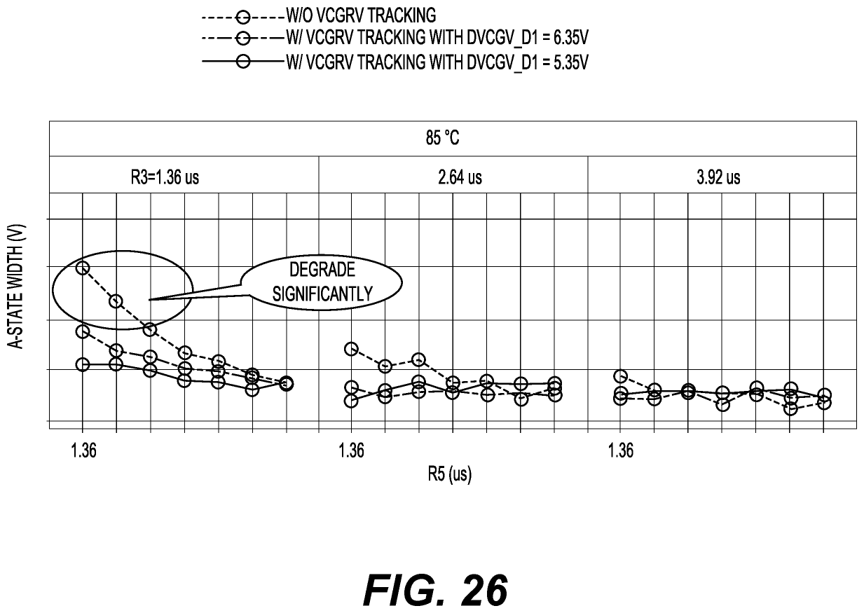

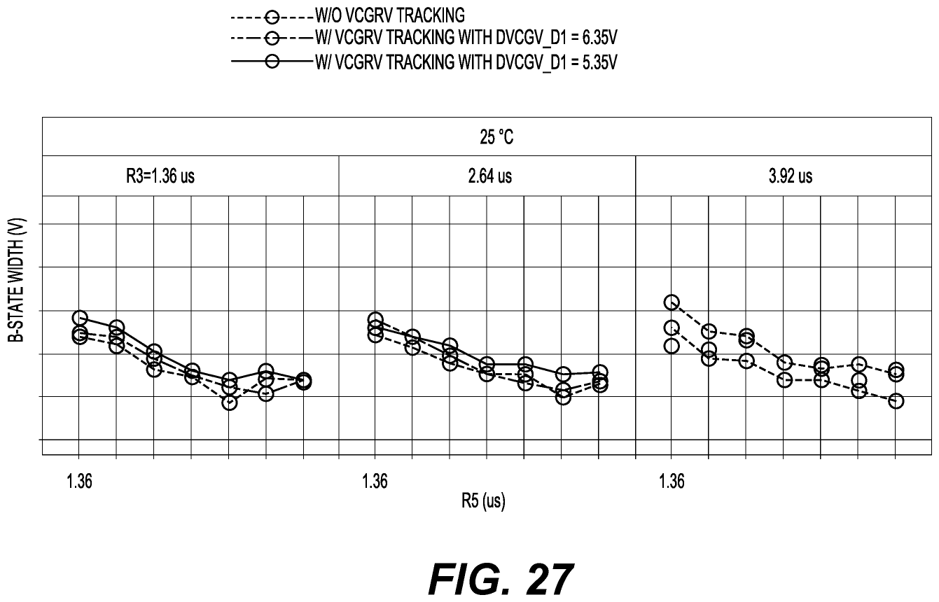

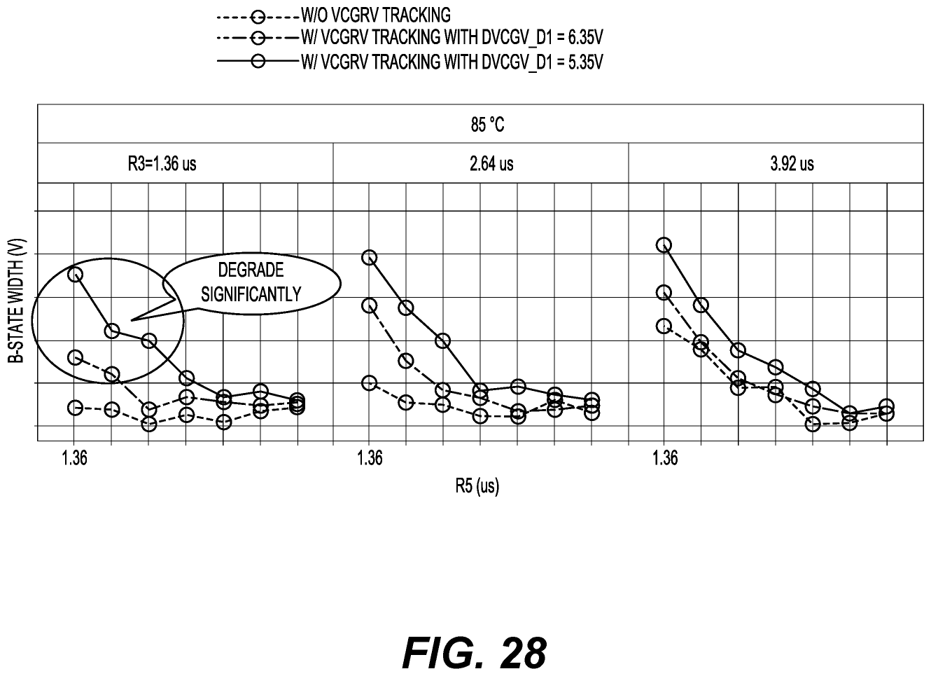

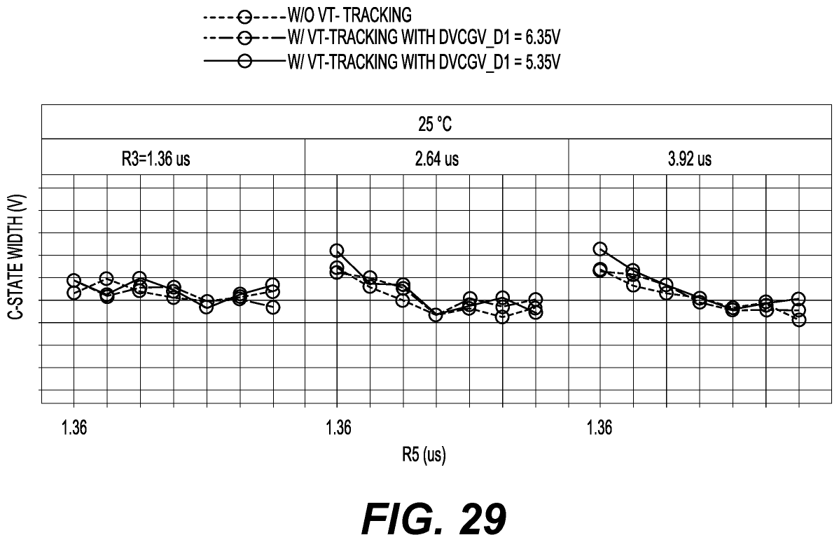

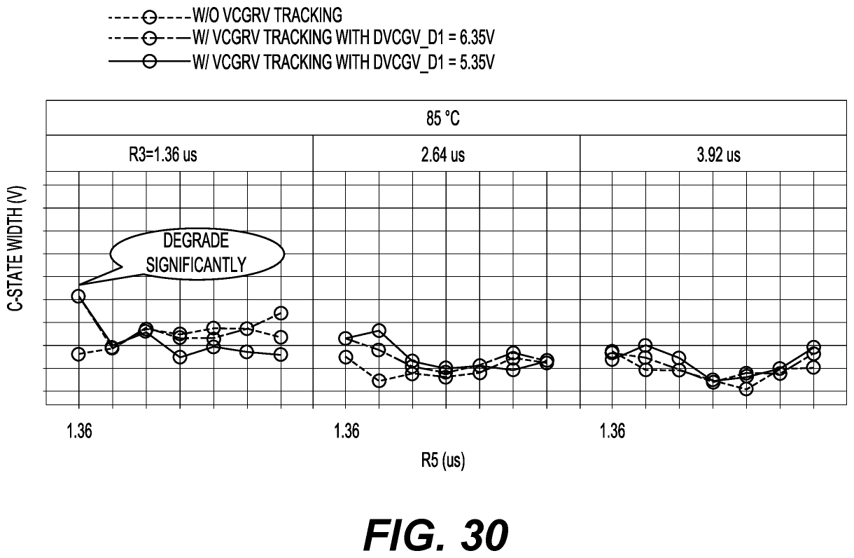

FIG. 25 shows a threshold voltage Vth distribution width for different length R3 and R5 time periods at 25 degrees Celsius. As the R3 and R5 time periods are shortened, the threshold voltage Vth distribution width for the A-state width degrades (widens) more significantly compared to the case when no VCGRV tracking is utilized as compared to when VCGRV tracking is utilized. In comparison, FIG. 26 shows a threshold voltage Vth distribution width for different length R3 and R5 time periods at 85 degrees Celsius for the A-state. The response or degradation with shorter timing is even stronger at high temperature, likely because metal resistance is higher at higher temperature. FIGS. 27 and 28 show a threshold voltage Vth distribution width for different length R3 and R5 time periods at 25 degrees Celsius for the B-state (FIG. 27) and at 85 degrees Celsius for the B-state (FIG. 28). As the fifth period R5 is shortened, B-state threshold voltage Vth distribution width degrades with and without VCGRV tracking. Similar to the A-state, the response or degradation with shorter timing is even stronger at high temperature. FIGS. 29 and 30 show a threshold voltage Vth distribution width for different length R3 and R5 time periods at 25 degrees Celsius for the C-state (FIG. 29) and at 85 degrees Celsius for the C-state (FIG. 30). The C-state threshold voltage Vth distribution width with and without VCGRV tracking do not show much of a difference. At R3=R5=1.36 micorseconds (us), without VCGRV tracking has less C-state Vt-width widening compared to with VCGRV tracking.

Clearly, changes may be made to what is described and illustrated herein without, however, departing from the scope defined in the accompanying claims. The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” “top”, “bottom”, and the like, may be used herein for ease of description to describe one element's or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptions used herein interpreted accordingly.

What is claimed is:

1. An apparatus, comprising:
a plurality of selected memory cells coupled to a selected word line and each storing a threshold voltage representative of a selected cell data programmed in a program-verify operation;
a plurality of unselected memory cells coupled to a neighbor word line disposed adjacent the selected word line; and
a control circuit coupled to the plurality of selected and the plurality of unselected memory cells and configured to ramp from at least one initial voltage applied to the neighbor word line directly to a target neighbor verify voltage without exceeding or falling below the target neighbor verify voltage thereby assisting the selected word line reach at least one verify reference voltage used in verifying the threshold voltage of each of the plurality of selected memory cells during at least one verify stage of the program-verify operation following a program stage of the program-verify operation.

2. The apparatus as set forth in claim 1, wherein the threshold voltage of each of the plurality of selected memory cells is within a common range of threshold voltages defining a plurality of data states associated with threshold voltage distributions of the threshold voltage and the at least one verify reference voltage includes a plurality of verify reference voltages each corresponding to one of the plurality of data states and the at least one verify stage includes a sequence of a plurality of verify stages and the control circuit is further configured to:
select and apply one of the plurality of verify reference voltages to the selected word line based on which of the plurality of data states is being verified during each of the plurality of verify stages, and
simultaneously adjust the target neighbor verify voltage applied to the neighbor word line according to the one of the plurality of verify reference voltages applied to the selected word line for each of the plurality of verify stages.

3. The apparatus as set forth in claim 2, wherein the at least one initial voltage applied to the neighbor word line includes a pass voltage causing the plurality of unselected memory cells to conduct electricity during the program stage and each of the plurality of verify stages includes a plurality of predetermined time periods and the control circuit is further configured to:
apply the pass voltage to the neighbor word line while applying a program voltage to the selected word line during the program operation before a first period of the plurality of predetermined time periods, and
ramp the pass voltage applied to the neighbor word line beginning before the first period of the plurality of predetermined time periods directly to the target neighbor verify voltage over a second period and a third period and a fourth period of the plurality of predetermined time periods without exceeding or falling below the target neighbor verify voltage to define a first ramped voltage waveform.

4. The apparatus as set forth in claim 3, wherein the at least one initial voltage applied to the neighbor word line includes a default read pass voltage causing the plurality of unselected memory cells to conduct electricity during the plurality of verify stages and each of the plurality of verify stages includes the plurality of predetermined time periods and the control circuit is further configured to:
apply the default read pass voltage to the neighbor word line after the program operation after the first period and the second period of the plurality of predetermined time periods, and
ramp the pass voltage applied to the neighbor word line beginning after the first period and the second period of the plurality of predetermined time periods directly to the target neighbor verify voltage over the third period and the fourth period and into a fifth period of the plurality of predetermined time periods without exceeding or falling below the target neighbor verify voltage to define a second ramped voltage waveform.

5. The apparatus as set forth in claim 4, wherein the plurality of data states includes a plurality of lower states associated with lower threshold voltages of the common range of threshold voltages and a plurality of upper states associated with upper threshold voltages of the common range of threshold voltages being larger in magnitude than the lower threshold voltages and the control circuit is further configured to:
apply at least one of the first ramped voltage waveform and the second ramped voltage waveform to the neighbor word line in response to one or more of the plurality of lower states of the plurality of data states being verified during one of the plurality of verify stages, and
apply the default read pass voltage to the neighbor word line in response to one or more of the plurality of upper states of the plurality of data states being verified during one of the plurality of verify stages.

6. The apparatus as set forth in claim 4, wherein the plurality of data states includes an erased state and a first data state and a second data state and a third data state and a fourth data state and a fifth data state and a sixth data state and a seventh data state each associated with different increasing threshold voltage distributions of the threshold voltage in the common range of threshold voltages and the control circuit is further configured to:
apply at least one of the first ramped voltage waveform and the second ramped voltage waveform to the neighbor word line in response to at least one of the first data state and the second data state and the third data state of the plurality of data states being verified during one of the plurality of verify stages, and
apply the default read pass voltage to the neighbor word line in response to at least one of the third data state and the fourth data state and the fifth data state and the sixth data state and the seventh data state of the plurality of data states being verified during one of the plurality of verify stages.

7. The apparatus as set forth in claim 1, wherein:
the threshold voltage of each of the plurality of selected memory cells is within a common range of threshold voltages defining a plurality of data states associated with threshold voltage distributions of the threshold voltage;
the at least one verify reference voltage includes a plurality of verify reference voltages each corresponding to one of the plurality of data states;
the at least one verify stage includes a sequence of a plurality of verify stages;
the at least one initial voltage applied to the neighbor word line is a pass voltage causing the plurality of unselected memory cells to conduct electricity during the program stage;
each of the plurality of verify stages includes a plurality of predetermined time periods; and
the control circuit is further configured to:
select and apply one of the plurality of verify reference voltages to the selected word line based on which of the plurality of data states is being verified during each of the plurality of verify stages, and
simultaneously ramp the pass voltage applied to the neighbor word line beginning before a first period of the plurality of predetermined time periods directly to a default read pass voltage over a second period and a third period and a fourth period of the plurality of predetermined time periods without exceeding or falling below the default read pass voltage, the default read pass voltage causing the plurality of unselected memory cells to conduct electricity during each of the plurality of verify stages.

8. A controller in communication with a memory apparatus including a plurality of selected memory cells coupled to a selected word line and each storing a threshold voltage representative of a selected cell data programmed in a program-verify operation and a plurality of unselected memory cells coupled to a neighbor word line disposed adjacent the selected word line, the controller configured to:
instruct the memory apparatus to ramp from at least one initial voltage applied to the neighbor word line directly to a target neighbor verify voltage without exceeding or falling below the target neighbor verify voltage thereby assisting the selected word line reach at least one verify reference voltage used in verifying the threshold voltage of each of the plurality of selected memory cells during at least one verify stage of the program-verify operation following a program stage of the program-verify operation.

9. The controller as set forth in claim 8, wherein the threshold voltage of each of the plurality of selected memory cells is within a common range of threshold voltages defining a plurality of data states associated with threshold voltage distributions of the threshold voltage and the at least one verify reference voltage includes a plurality of verify reference voltages each corresponding to one of the plurality of data states and the at least one verify stage includes a sequence of a plurality of verify stages and the controller is further configured to:
select and instruct the memory apparatus to apply one of the plurality of verify reference voltages to the selected word line based on which of the plurality of data states is being verified during each of the plurality of verify stages, and
instruct the memory apparatus to simultaneously adjust the target neighbor verify voltage applied to the neighbor word line according to the one of the plurality of verify reference voltages applied to the selected word line for each of the plurality of verify stages.

10. The controller as set forth in claim 9, wherein the at least one initial voltage applied to the neighbor word line includes a pass voltage causing the plurality of unselected memory cells to conduct electricity during the program stage and each of the plurality of verify stages includes a plurality of predetermined time periods and the controller is further configured to:
instruct the memory apparatus to apply the pass voltage to the neighbor word line while applying a program voltage to the selected word line during the program operation before a first period of the plurality of predetermined time periods, and
instruct the memory apparatus to ramp the pass voltage applied to the neighbor word line beginning before the first period of the plurality of predetermined time periods directly to the target neighbor verify voltage over a second period and a third period and a fourth period of the plurality of predetermined time periods without exceeding or falling below the target neighbor verify voltage to define a first ramped voltage waveform.

11. The controller as set forth in claim 10, wherein the at least one initial voltage applied to the neighbor word line includes a default read pass voltage causing the plurality of unselected memory cells to conduct electricity during the plurality of verify stages and each of the plurality of verify stages includes the plurality of predetermined time periods and the controller is further configured to:
instruct the memory apparatus to apply the default read pass voltage to the neighbor word line after the program operation after the first period and the second period of the plurality of predetermined time periods, and
instruct the memory apparatus to ramp the pass voltage applied to the neighbor word line beginning after the first period and the second period of the plurality of predetermined time periods directly to the target neighbor verify voltage over the third period and the fourth period and into a fifth period of the plurality of predetermined time periods without exceeding or falling below the target neighbor verify voltage to define a second ramped voltage waveform.

12. The controller as set forth in claim 11, wherein the plurality of data states includes a plurality of lower states associated with lower threshold voltages of the common range of threshold voltages and a plurality of upper states associated with upper threshold voltages of the common range of threshold voltages being larger in magnitude than the lower threshold voltages and the controller is further configured to:
instruct the memory apparatus to apply at least one of the first ramped voltage waveform and the second ramped voltage waveform to the neighbor word line in response to one or more of the plurality of lower states of the plurality of data states being verified during one of the plurality of verify stages, and
instruct the memory apparatus to apply the default read pass voltage to the neighbor word line in response to one or more of the plurality of upper states of the plurality of data states being verified during one of the plurality of verify stages.

13. The controller as set forth in claim 11, wherein the plurality of data states includes an erased state and a first data state and a second data state and a third data state and a fourth data state and a fifth data state and a sixth data state and a seventh data state each associated with different increasing threshold voltage distributions of the threshold voltage in the common range of threshold voltages and the controller is further configured to:
instruct the memory apparatus to apply at least one of the first ramped voltage waveform and the second ramped voltage waveform to the neighbor word line in response to at least one of the first data state and the second data state and the third data state of the plurality of data states being verified during one of the plurality of verify stages, and
instruct the memory apparatus to apply the default read pass voltage to the neighbor word line in response to at least one of the third data state and the fourth data state and the fifth data state and the sixth data state and the seventh data state of the plurality of data states being verified during one of the plurality of verify stages.

14. A method of operating a memory apparatus including a plurality of selected memory cells coupled to a selected word line and each storing a threshold voltage representative of a selected cell data programmed in a program-verify operation and a plurality of unselected memory cells coupled to a neighbor word line disposed adjacent the selected word line, the method including the steps of:
ramping from at least one initial voltage applied to the neighbor word line directly to a target neighbor verify voltage without exceeding or falling below the target neighbor verify voltage during at least one verify stage of the program-verify operation following the program stage of the program-verify operation; and
assisting the selected word line reach at least one verify reference voltage used in verifying the threshold voltage of each of the plurality of selected memory cells.

15. The method as set forth in claim 14, wherein the threshold voltage of each of the plurality of selected memory cells is within a common range of threshold voltages defining a plurality of data states associated with threshold voltage distributions of the threshold voltage and the at least one verify reference voltage includes a plurality of verify reference voltages each corresponding to one of the plurality of data states and the at least one verify stage includes a sequence of a plurality of verify stages, the method further including the steps of:
selecting and applying one of the plurality of verify reference voltages to the selected word line based on which of the plurality of data states is being verified during each of the plurality of verify stages; and
simultaneously adjusting the target neighbor verify voltage applied to the neighbor word line according to the one of the plurality of verify reference voltages applied to the selected word line for each of the plurality of verify stages.

16. The method as set forth in claim 15, wherein the at least one initial voltage applied to the neighbor word line includes a pass voltage causing the plurality of unselected memory cells to conduct electricity during the program stage and each of the plurality of verify stages includes a plurality of predetermined time periods and the method further includes the steps of:
applying the pass voltage to the neighbor word line while applying a program voltage to the selected word line during the program operation before a first period of the plurality of predetermined time periods; and
ramping the pass voltage applied to the neighbor word line beginning before the first period of the plurality of predetermined time periods directly to the target neighbor verify voltage over a second period and a third period and a fourth period of the plurality of predetermined time periods without exceeding or falling below the target neighbor verify voltage to define a first ramped voltage waveform.

17. The method as set forth in claim 16, wherein the at least one initial voltage applied to the neighbor word line includes a default read pass voltage causing the plurality of unselected memory cells to conduct electricity during the plurality of verify stages and each of the plurality of verify stages includes the plurality of predetermined time periods, the method further including the steps of:
applying the default read pass voltage to the neighbor word line after the program operation after the first period and the second period of the plurality of predetermined time periods, and
ramping the pass voltage applied to the neighbor word line beginning after the first period and the second period of the plurality of predetermined time periods directly to the target neighbor verify voltage over the third period and the fourth period and into a fifth period of the plurality of predetermined time periods without exceeding or falling below the target neighbor verify voltage to define a second ramped voltage waveform.

18. The method as set forth in claim 17, wherein the plurality of data states includes a plurality of lower states associated with lower threshold voltages of the common range of threshold voltages and a plurality of upper states associated with upper threshold voltages of the common range of threshold voltages being larger in magnitude than the lower threshold voltages, the method further including the steps of:
applying at least one of the first ramped voltage waveform and the second ramped voltage waveform to the neighbor word line in response to one or more of the plurality of lower states of the plurality of data states being verified during one of the plurality of verify stages; and
applying the default read pass voltage to the neighbor word line in response to one or more of the plurality of upper states of the plurality of data states being verified during one of the plurality of verify stages.

19. The method as set forth in claim 17, wherein the plurality of data states includes an erased state and a first data state and a second data state and a third data state and a fourth data state and a fifth data state and a sixth data state and a seventh data state each associated with different increasing threshold voltage distributions of the threshold voltage in the common range of threshold voltages, the method further including the steps of:
applying at least one of the first ramped voltage waveform and the second ramped voltage waveform to the neighbor word line in response to at least one of the first data state and the second data state and the third data state of the plurality of data states being verified during one of the plurality of verify stages; and
applying the default read pass voltage to the neighbor word line in response to at least one of the third data state and the fourth data state and the fifth data state and the sixth data state and the seventh data state of the plurality of data states being verified during one of the plurality of verify stages.

20. The method as set forth in claim 14, wherein:
the threshold voltage of each of the plurality of selected memory cells is within a common range of threshold voltages defining a plurality of data states associated with threshold voltage distributions of the threshold voltage;
the at least one verify reference voltage includes a plurality of verify reference voltages each corresponding to one of the plurality of data states;
the at least one verify stage includes a sequence of a plurality of verify stages;
the at least one initial voltage applied to the neighbor word line is a pass voltage causing the plurality of unselected memory cells to conduct electricity during the program operation;
each of the plurality of verify stages includes a plurality of predetermined time periods; and the method further includes the steps of:
selecting and applying one of the plurality of verify reference voltages to the selected word line based on which of the plurality of data states is being verified during each of the plurality of verify stages, and
simultaneously ramping the pass voltage applied to the neighbor word line beginning before a first period of the plurality of predetermined time periods directly to a default read pass voltage over a second period and a third period and a fourth period of the plurality of predetermined time periods without exceeding or falling below the default read pass voltage, the default read pass voltage causing the plurality of unselected memory cells to conduct electricity during the verify operation.
